(19) United States
(12) Patent Application Publication
(10) Pub. No.: US 2026/0150958 A1
(43) Pub. Date: Jun. 4, 2026

(54) SUBSTRATE PROCESSING DEVICE

(71) Applicant: SCREEN Holdings Co., Ltd., Kyoto (JP)

(72) Inventors: Toshihiro ABE, Kyoto-shi (JP); Tomoyuki SHINOHARA, Kyoto-shi (JP); Kazuma FUNAHASHI, Kyoto-shi (JP); Hikari IKEMOTO, Kyoto-shi (JP)

(73) Assignee: SCREEN Holdings Co., Ltd., Kyoto (JP)

(21) Appl. No.: 19/406,936

(22) Filed: Dec. 3, 2025

(30) Foreign Application Priority Data
Dec. 4, 2024 (JP) 2024-211837

(51) Int. Cl. A46B 13/04; B25J 9/02; B25J 9/16; B25J 11/00

(52) U.S. Cl. CPC A46B 13/04; B25J 9/023; B25J 9/1633; B25J 11/0095; A46B 2200/3073; H10P 72/0412

(57) ABSTRACT

The substrate processing device includes: a cleaning tool cleaning a substrate; a load transmission member having first and second force transmission points; and a linear guide movably supporting the load transmission member downward (−Z direction) and upward direction (+Z direction), and further includes: an air cylinder device applying a downwardly directed force to the first force transmission point of the load transmission member; and a load sensor having a contact member able to contact the second force transmission point of the load transmission member and detecting a force acting downwardly from the second force transmission point to the contact member. The first and second force transmission points and the linear guide of the load transmission member overlap with a virtual line extending in a horizontal direction when viewed in a plan view.

### CROSS REFERENCE TO RELATED APPLICATIONS

This application claims the priority benefit of Japanese Patent Application No. 2024-211837, filed on Dec. 4, 2024. The entirety of the above-mentioned patent application is hereby incorporated by reference herein and made a part of this specification.

### BACKGROUND

### Technical Field

The disclosure relates to a substrate processing device that performs processing by bringing a cleaning tool into contact with a substrate.

### Description of Related Art

A substrate processing device is used to perform various processes on a substrate such as a semiconductor substrate, a flat panel display (FPD) substrate for a liquid crystal display device or an organic electro-luminescence (EL) display device, an optical disk substrate, a magnetic disk substrate, a magneto-optical disk substrate, a photomask substrate, a ceramic substrate, or a solar cell substrate.

As an example of such substrate processing device, the substrate processing device described in Japanese Patent Application Laid-Open Publication No. 2009-206139 includes a back surface cleaning processing unit that scrub-cleans the back surface (one surface) of a substrate. The back surface cleaning processing unit includes a spin chuck, a brush, a holding arm, and a brush moving mechanism.

The spin chuck holds the substrate in a horizontal posture to be rotatable. The holding arm holds the brush. In addition, the brush moving mechanism is connected to the holding arm. The brush moving mechanism brings the brush into contact with one surface of the substrate that is held and rotated by the spin chuck by moving the holding arm. In addition, the brush moving mechanism moves the brush on the one surface of the substrate by further moving the holding arm. Accordingly, the one surface of the substrate is cleaned.

In the holding arm, the brush is attached to a lower end part of a rotating shaft that extends in the upper-lower direction. In addition, the rotating shaft is supported by a housing of the holding arm via a coil spring. Therefore, in a state where the brush does not contact the substrate, the weight of the configuration including the rotating shaft and the brush is offset by the elastic force of the coil spring.

Furthermore, the holding arm incorporates a bracket and a pressing actuator for pressing the rotating shaft downward to press the brush against the one substrate in a state where the brush contacts the one surface of the substrate. The degree of cleaning force against the one surface of the substrate differs according to the pressing force (pressing pressure) acting on the one surface of the substrate from the brush. Therefore, the pressing actuator presses the rotating shaft toward the substrate with a predetermined force to obtain a predetermined degree of cleaning force during cleaning of one surface of the substrate.

The holding arm further incorporates a pressure sensor. The pressure sensor receives the driving force generated by the pressing actuator via the bracket and detects the driving force as the pressing pressure exerted by the pressing actuator.

In the substrate processing device, the pressing pressure of the brush against the substrate is set in advance based on the detection value of the pressure sensor. Therefore, in the case where the pressing pressure detected by the pressure sensor is not accurate, it becomes difficult to clean the substrate under a desired condition.

The disclosure provides a substrate processing device that improves the accuracy of cleaning a substrate using a cleaning tool.

### SUMMARY

A substrate processing device according to an aspect of the disclosure includes: a cleaning tool, cleaning a substrate; a force transmission body, having a first portion and a second portion; a linear guide, supporting the force transmission body to be movable in a first direction and a second direction opposite to the first direction; a force applying part, applying a force in the first direction or a force in the second direction to the first portion of the force transmission body; and a force detection part, having a contact part able to contact the second portion and detecting a force acting in the first direction from the second portion to the contact part. The force transmission part is able to transmit the force applied from the force applying part to the first portion to the cleaning tool. The first portion, the second portion, and the linear guide overlap with a virtual line that intersects the first direction and the second direction when viewed in the first direction.

### BRIEF DESCRIPTION OF THE DRAWINGS

FIG. 1 is a schematic plan view of a substrate cleaning device according to an embodiment of the disclosure.

FIG. 2 is a flowchart showing the flow of general processes executed by a control part in the substrate cleaning device of FIG. 1.

FIGS. 3A and 3B are diagrams for describing an example of an operation during a substrate cleaning process performed by the substrate cleaning device of FIG. 1.

FIG. 4 is a schematic plan view of a brush arm of FIG. 1 when viewed in −Z direction.

FIG. 5 is a schematic side view of one side of the brush arm of FIG. 1 when viewed in +X direction.

FIG. 6 is a schematic side view of the other side of the brush arm of FIG. 1 when viewed in −X direction.

FIG. 7 is a schematic end view of one end of the brush arm of FIG. 1 when viewed in +Y direction.

FIGS. 8A to 8C are diagrams for describing a brush pressing force adjustment process.

FIGS. 9A to 9D are diagrams for defining a moment that may occur in a linear guide.

FIG. 10 is a plan view of the linear guide built in the brush arm of FIG. 1.

FIG. 11 is a schematic side view of one side of the linear guide of FIG. 10 when viewed in +Y direction.

FIG. 12 is a cross-sectional view taken along a line Q-Q of FIG. 11.

FIG. 13 is a schematic plan view of a brush arm according to a comparative example when viewed in −Z direction.

FIG. 14 is a schematic view of one side of the brush arm of FIG. 13 when viewed in +X direction.

FIGS. 15A and 15B are diagrams showing pressing force detection experiment results.

FIG. 16 is a block diagram showing the configuration of the control system of the substrate cleaning device of FIG. 1.

FIG. 17 is a flowchart of a brush pressing force adjustment process.

FIG. 18 is a schematic plan view showing an example of a substrate processing device including the substrate cleaning device of FIG. 1.

FIGS. 19A and 19B are diagrams showing an example of a brush arm according to another embodiment.

FIGS. 20A and 20B are diagrams showing an example of a brush arm according to still another embodiment.

### DESCRIPTION OF THE EMBODIMENTS

According to the disclosure, it becomes possible to improve the accuracy of substrate cleaning using a cleaning tool.

Hereinafter, a substrate processing device according to an embodiment of the disclosure will be described with reference to the drawings. In the following description, a substrate refers to a flat panel display (FPD) substrate used in a liquid crystal display device or an organic electro luminescence (EL) display device, a semiconductor substrate, an optical disk substrate, a magnetic disk substrate, a magneto-optical disk substrate, a photomask substrate, a ceramic substrate, a solar cell substrate, or the like.

In this embodiment, the substrate has a circular shape when viewed in a plan view, except for a portion where a notch is formed. Also, the substrate has a front surface that is a circuit formation surface and a back surface that is opposite to the circuit formation surface. In the following description, regardless of the front surface and the back surface of the substrate, the surface facing upward between the two surfaces of the substrate is referred to as the upper surface of the substrate, and the surface facing downward between the two surfaces of the substrate is referred to as the lower surface of the substrate.

The substrate processing device described below is a substrate cleaning device that performs a cleaning process on a substrate as a processing target by using a brush. During the cleaning process, a predetermined cleaning liquid is supplied to the upper surface of the substrate while a brush is pressed against the upper surface of the substrate.

### 1. Overall Configuration of Substrate Cleaning Device

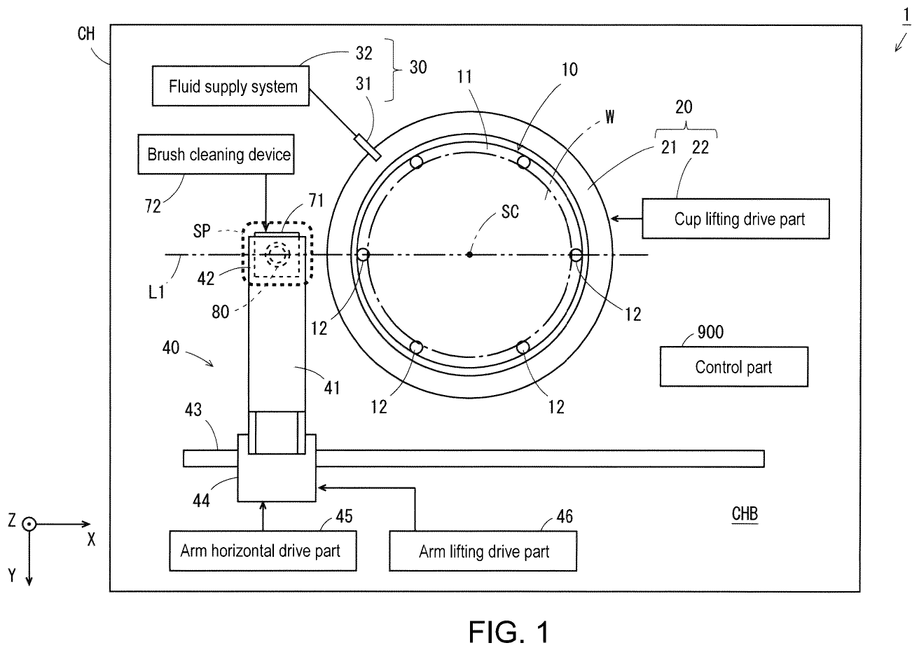

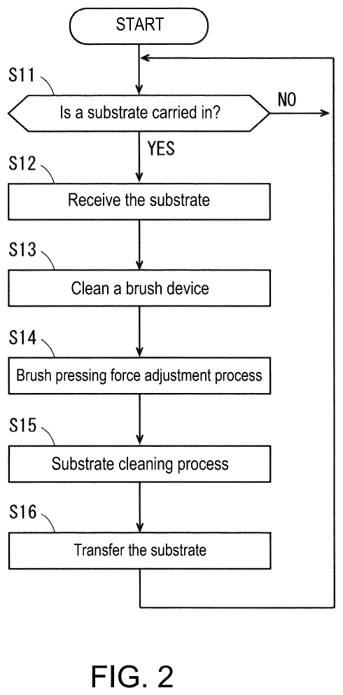

FIG. 1 is a schematic plan view of a substrate cleaning device according to an embodiment of the disclosure. In FIG. 1 and predetermined figures from FIG. 2 onward, arrows indicating X-direction, Y-direction, and Z-direction that are orthogonal to each other are attached to clarify positional relationships. X-direction and Y-direction are orthogonal to each other in a horizontal plane. In this embodiment, X-direction corresponds to the left-right direction of the substrate cleaning device 1, and Y-direction corresponds to the front-rear direction of the substrate cleaning device 1. Also, Z-direction corresponds to the upper-lower direction (vertical direction) of the substrate cleaning device 1.

In X-direction, to distinguish between the direction toward which the arrow points and the opposite direction, the direction toward which the arrow points is referred to as +X direction, and the opposite direction is referred to as −X direction. Also, in Y-direction, to distinguish between the direction toward which the arrow points and the opposite direction, the direction toward which the arrow points is referred to as +Y direction, and the opposite direction is referred to as −Y direction. Also, in Z-direction, to distinguish between the direction toward which the arrow points and the opposite direction, the direction toward which the arrow points is referred to as +Z direction, and the opposite direction is referred to as −Z direction.

As shown in FIG. 1, the substrate cleaning device 1 has a configuration in which multiple components are accommodated in a chamber CH, and includes a substrate holding device 10, a cup device 20, a nozzle device 30, a brush arm device 40, a standby pod 71, a brush cleaning device 72, a brush device 80, and a control part 900.

The chamber CH has four side surfaces, a ceiling surface, and a floor surface (bottom surface) CHB. In one side surface of the chamber CH, a transport opening (not shown) is formed for transporting substrates between the inside of the chamber CH and the outside of the chamber CH.

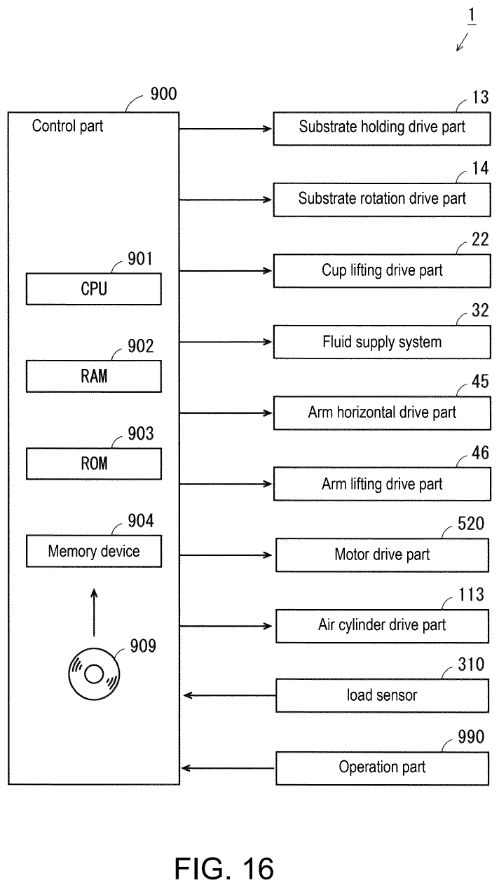

The substrate holding device 10 is provided at substantially the center of the floor surface CHB of the chamber CH. The substrate holding device 10 includes a spin base 11, multiple holding pins 12, a substrate holding drive part 13 (FIG. 16), and a substrate rotation drive part 14 (FIG. 16). The substrate rotation drive part 14 includes, for example, a motor, and is fixed to the floor surface CHB of the chamber CH, so the rotation shaft of the motor faces upward. The disc-shaped spin base 11 is attached to the upper end part of the rotation shaft.

The spin base 11 has an outer diameter larger than the substrate W as the processing target. The holding pins 12 are provided at the upper surface peripheral edge part of the spin base 11. Each of the holding pins 12 has a contact part. In the state where the substrate W is disposed on the spin base 11, each holding pin 12 is configured to be capable of transitioning between a holding state in which the contact part contacts the outer peripheral end part of the substrate W and a release state in which the contact part is separated from the substrate W. The substrate holding drive part 13 includes, for example, a magnet, and switches each holding pin 12 between the holding state and the release state by using the magnetic force of the magnet. The substrate W is held on the spin base 11 through the contact parts of the holding pins 12 in the holding state contacting multiple portions of the outer peripheral end part of the substrate W. In FIG. 1, the outer shape of the substrate W held by the substrate holding device 10 is shown by a dash-dot line.

The cup device 20 includes a cup body 21 and a cup lifting drive part 22. The cup body 21 has a substantially cylindrical shape, and is provided to surround the spin base 11 when viewed in a plan view and extend in Z-direction. Also, the cup body 21 is provided to be movable in Z-direction.

The cup lifting drive part 22 includes an actuator, such as a motor or an air cylinder, and moves the cup body 21 between a cup upper position and a cup lower position determined in advance. The cup upper position is a height position (position in Z-direction) of the cup body 21 when the upper end part of the cup body 21 is positioned above the substrate W held by the substrate holding device 10. The cup lower position is a height position of the cup body 21 when the upper end part of the cup body 21 is positioned below the substrate W held by the substrate holding device 10.

The nozzle device 30 includes a fluid nozzle 31 and a fluid supply system 32. The fluid nozzle 31 is provided at a predetermined position above the substrate holding device 10 and the cup device 20. The fluid nozzle 31 is fixed so that the discharge port of the fluid nozzle 31 faces a rotation center SC of the spin base 11 in the substrate holding device 10. The fluid supply system 32 supplies a cleaning liquid to the fluid nozzle 31 during the cleaning process of the substrate W. Accordingly, the cleaning liquid is supplied to the upper surface of the substrate W held by the substrate holding device 10. The cleaning liquid is, for example, pure water (deionized water). The cleaning liquid may use carbonated water, ozone water, hydrogen water, electrolyzed ion water, a mixed solution of ammonia and hydrogen peroxide water (SC1), or tetramethylammonium hydroxide (TMAH), etc., instead of pure water. Also, the nozzle device 30 may be configured to be capable of injecting gas, such as inert gas, from the fluid nozzle 31. Furthermore, the nozzle device 30 may have multiple fluid nozzles 31 capable of discharging or injecting mutually different fluids.

The brush arm device 40 includes a brush arm 41, a guide rail 43, an arm support part 44, an arm horizontal drive part 45, and an arm lifting drive part 46. In the chamber CH, the guide rail 43 is provided to be adjacent to the substrate holding device 10 in Y-direction. The guide rail 43 extends in X-direction.

The arm support part 44 is provided to be movable in X-direction along the guide rail 43. The arm horizontal drive part 45 in this example includes a motor, and moves the arm support part 44 in X-direction based on the control of the control part 900 to be described later. The brush arm 41 is supported by the arm support part 44 to be movable in Z-direction (capable of lifting and lowering). The arm lifting drive part 46 in this example includes a motor, and moves the brush arm 41 in Z-direction based on the control of the control part 900 to be described later.

The brush arm 41 has a substantially rectangular parallelepiped shape and extends in Y-direction from the arm support part 44 toward the substrate holding device 10. The tip part of the brush arm 41 is configured as a brush support part 42 to be able to support the brush device 80 used for cleaning the substrate W. In the substrate cleaning device 1 of FIG. 1, the brush support part 42 is positioned on a virtual line L1 that passes through the rotation center SC of the spin base 11 and extends in X-direction when viewed in a plan view.

The brush device 80 includes a brush and has a cleaning surface capable of contacting the upper surface of the substrate W. The brush is formed by, for example, a polyvinyl alcohol (PVA) sponge or a PVA sponge with abrasive particles dispersed therein.

When viewed in a plan view, the standby pod 71 and the substrate holding device 10 are arranged on the virtual line L1. The standby pod 71 is configured to be capable of accommodating the brush device 80 supported by the brush support part 42.

The brush cleaning device 72 is configured to be capable of injecting a cleaning liquid into the standby pod 71. In a state where the brush device 80 is accommodated in the standby pod 71, the cleaning liquid is injected from the brush cleaning device 72 into the standby pod 71. Accordingly, the brush device 80 is cleaned.

As shown by a thick dotted line frame in FIG. 1, in the substrate cleaning device 1, a standby position SP is set at a position overlapping the standby pod 71 when viewed in a plan view. The control part 900 controls the operation of each part of the substrate cleaning device 1. Details of the control part 900 will be described later.

### 2. Flow of General Processes in the Substrate Cleaning Device

FIG. 2 is a flowchart showing the flow of general processes executed by the control part 900 in the substrate cleaning device 1 of FIG. 1. In the initial state, the brush device 80 is accommodated in the standby pod 71.

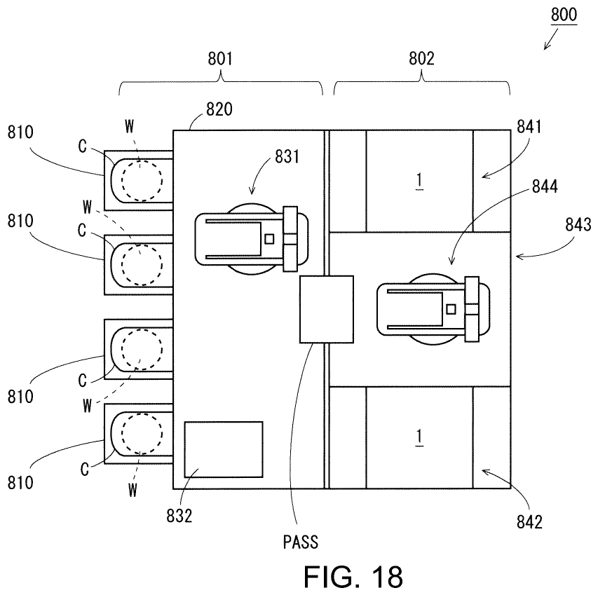

In a state where the power of the substrate cleaning device 1 is turned on and no substrate W is present in the chamber CH, the control part 900 determines whether the substrate W is carried in, as shown in FIG. 2 (Step S11). Whether the substrate W is carried in can be determined based on the operating state of a robot external to the chamber CH (such as a main robot 844 of FIG. 18 be described later).

In the case where the substrate W is not carried in, the processing of Step S11 is repeated. Meanwhile, when the substrate W is carried in, the control part 900 performs reception of the substrate W that is carried into the chamber CH by controlling the substrate holding device 10 and the like of FIG. 1 (Step S12). Accordingly, the substrate W is mounted on the substrate holding device 10 and held.

During or after the processing of Step S12, the control part 900 controls the brush cleaning device 72 of FIG. 1 to inject the cleaning liquid to the brush device 80 accommodated in the standby pod 71, and cleans the brush device 80 (Step S13).

After cleaning of the brush device 80, the control part 900 stops the injection of the cleaning liquid to the brush device 80 and performs a brush pressing force adjustment process (Step S14). The brush arm 41 of FIG. 1 is capable of applying a downward pressing force (load) to the brush device 80 supported by the brush support part 42. Accordingly, the brush arm 41 can press the brush device 80 against the substrate W in a state of being held at a predetermined height position (position in Z-direction) during the cleaning process of the substrate W.

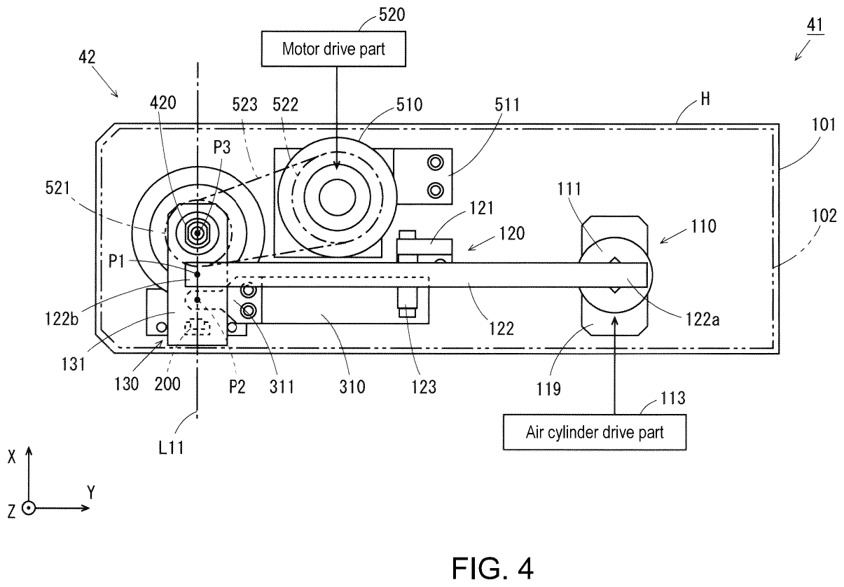

The brush pressing force adjustment process is a process for adjusting the operating condition of an air cylinder device 110 (FIG. 4) to be described later, so that the brush device 80 is pressed against the substrate W with a predetermined pressing force during the subsequent cleaning process of the substrate W. Details of the brush pressing force adjustment process will be described later.

Next, the control part 900 performs the cleaning process of the substrate W by controlling the nozzle device 30 and the brush arm device 40 of FIG. 1 (Step S15). After the cleaning process of the substrate W, the control part 900 controls the substrate holding device 10 and the like of FIG. 1 to transfer the substrate W to a robot external to the chamber CH (such as the main robot 844 of FIG. 18 to be described later) (Step S16). Accordingly, the processing returns to Step S11. In the series of processing, the processing of Step S14 may be performed before the processing of Step S13, or may be performed simultaneously with the processing of Step S12.

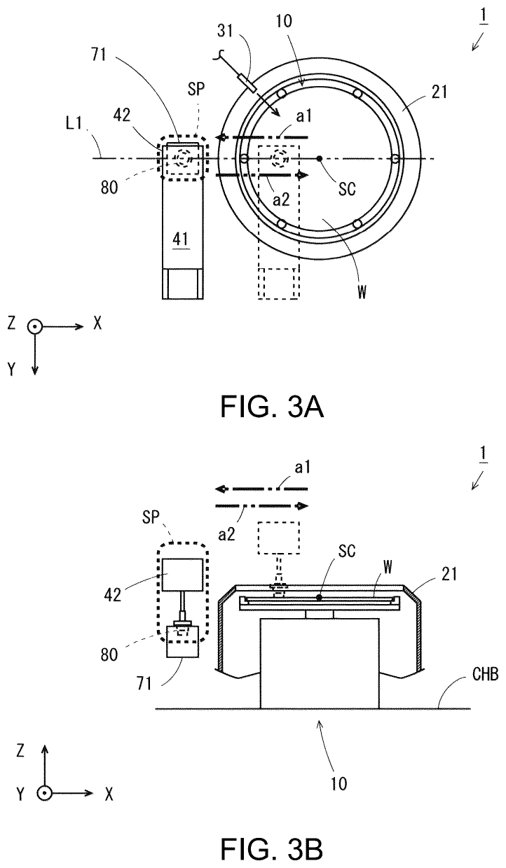

FIGS. 3A and 3B are diagrams for describing an example of an operation during the cleaning process of the substrate W performed by the substrate cleaning device 1 of FIG. 1. FIG. 3A is a schematic plan view of the substrate cleaning device 1. Also, in FIG. 3B, a schematic side view of one side of the substrate cleaning device 1 as viewed in −Y direction is shown.

As described above, immediately before the cleaning process of the substrate W, the brush pressing force adjustment process is performed in a state where the brush device 80 is accommodated in the standby pod 71. Therefore, even in the initial state of the cleaning process of the substrate W, the brush device 80 is accommodated in the standby pod 71. Also, in the initial state, the cup body 21 is at the cup lower position, and the discharge of the cleaning liquid by the fluid nozzle 31 is stopped.

When the cleaning process of the substrate W is started, the substrate W held by the substrate holding device 10 is rotated at a predetermined rotation speed. Also, the cup body 21 is held at the cup upper position. Furthermore, the cleaning liquid is discharged from the fluid nozzle 31 toward the rotating substrate W.

In this state, the arm horizontal drive part 45 and the arm lifting drive part 46 of FIG. 1 operate to move the brush arm 41 in Z-direction and X-direction. Accordingly, the brush device 80 supported by the brush support part 42 is lifted from the standby pod 71 and pressed against the upper surface of the rotating substrate W. In this state, as shown by thick dash-double-dot line arrows a1 and a2 in FIGS. 3A and 3B, the brush device 80 is moved along a virtual line L1 extending in X-direction when viewed in a plan view. In this manner, the upper surface of the substrate W is cleaned.

When the upper surface of the substrate W is cleaned, the brush device 80 is returned to the initial state position. Also, the discharge of the cleaning liquid by the fluid nozzle 31 is stopped, and the rotation of the substrate W by the substrate holding device 10 is stopped. Furthermore, the cup body 21 moves from the cup upper position to the cup lower position. Accordingly, the cleaning process of the substrate W is completed.

In the example of FIGS. 3A and 3B, the brush device 80 reciprocates between the outer peripheral end part of the substrate W and the rotation center SC of the spin base 11, but the substrate W may also be cleaned by moving from one end part to the other end part of the substrate W along the virtual line L1. Alternatively, the brush device 80 may clean the substrate W by moving only once between the outer peripheral end part of the substrate W and the rotation center SC of the spin base 11.

### 3. Configuration of Brush Arm 41

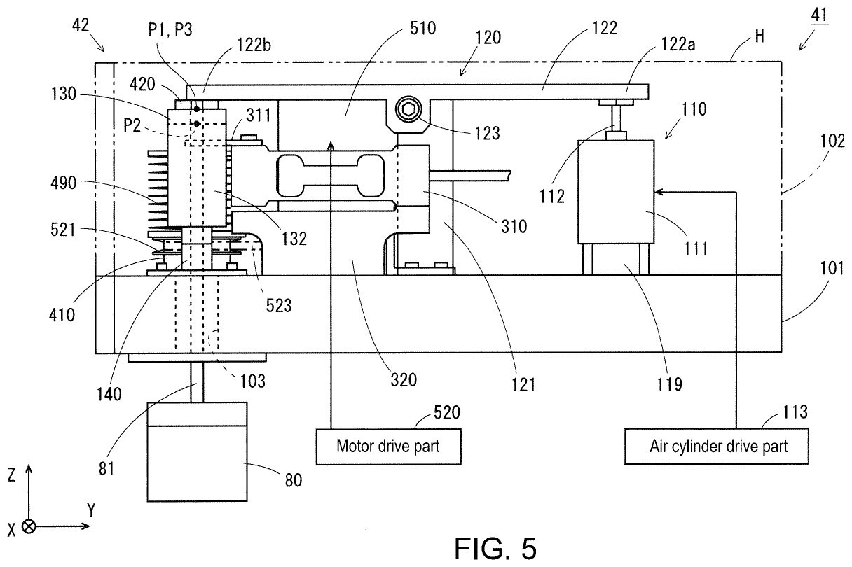

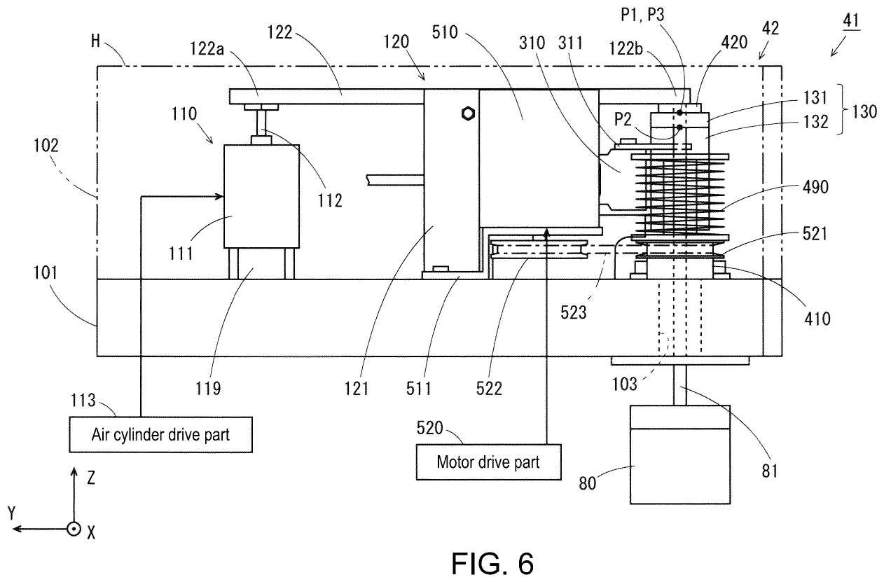

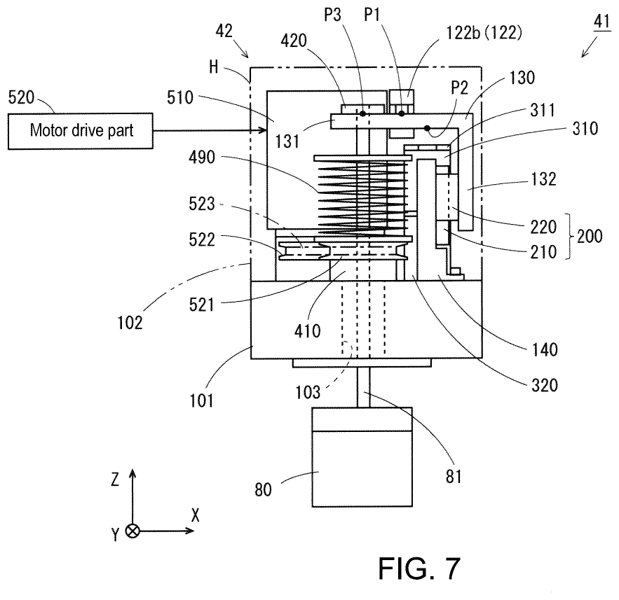

FIG. 4 is a schematic plan view of one side of the brush arm 41 of FIG. 1 when viewed in −Z direction. FIG. 5 is a schematic side view of one side of the brush arm 41 of FIG. 1 when viewed in +X direction. FIG. 6 is a schematic side view of the other side of the brush arm 41 of FIG. 1 when viewed in −X direction. FIG. 7 is a schematic end view of one end of the brush arm 41 of FIG. 1 when viewed in +Y direction.

The brush arm 41 according to the embodiment has a configuration in which multiple components are accommodated within a housing H. The housing H includes a base member 101 and a cover member 102. The base member 101 is configured with a rectangular long plate member, and one end part thereof is attached to the arm support part 44 of FIG. 1. Accordingly, the base member 101 is supported by the arm support part 44 in a state extending in −Y direction from the arm support part 44. In the brush arm 41 of FIG. 4 to FIG. 7, the end part of the base member 101 facing +Y direction serves as the attachment portion to the arm support part 44.

The cover member 102 has a box-like shape with an open lower end part, and is configured to be attachable to the base member 101. By attaching the cover member 102 onto the base member 101, an accommodation space for multiple components is formed on the base member 101. In FIG. 4 to FIG. 7, the cover member 102 is shown by a dash-double-dot line so that the internal configuration of the brush arm 41 can be easily understood. Also, the illustration of some components within the housing H is appropriately omitted.

The base member 101 has a rectangular flat upper surface. As shown in FIG. 4, on the upper surface of the base member 101, an air cylinder device 110 is provided via a cylinder base 119 at a position shifted in +Y direction from the central portion of the base member 101. As shown in FIG. 5, the air cylinder device 110 includes a cylinder body 111 and a cylinder rod 112. The cylinder body 111 is fixed onto the cylinder base 119 such that the axis thereof extends in Z direction.

Inside the cylinder body 111, a piston (not shown) is provided. The cylinder rod 112 is connected to the piston and is provided to extend from the piston toward the upper side of the cylinder body 111. A portion of the cylinder rod 112 including the upper end part protrudes above the cylinder body 111 and is exposed.

An air cylinder drive part 113 provided outside the brush arm 41 is connected to the cylinder body 111 via piping (not shown). The air cylinder drive part 113 includes, for example, one or multiple electro-pneumatic regulators. The air cylinder drive part 113 operates based on the control of the control part 900 of FIG. 1 and supplies air to the cylinder body 111. In this case, the pressure within the cylinder body 111 is adjusted, and a force corresponding to the adjusted pressure is generated in the cylinder rod 112.

Above the air cylinder device 110, a beam member 122 that forms a portion of a pressing mechanism 120 is provided. The pressing mechanism 120 will be described. The pressing mechanism 120 includes a pillar member 121, a beam member 122, and a linking shaft 123.

The pillar member 121 is attached to a substantially central portion of the upper surface of the base member 101, and extends in +Z direction from the upper surface of the base member 101 to a position near the upper end part of the housing H. The beam member 122 is formed with a rod-shaped member having high rigidity. The central portion of the beam member 122 is attached to the upper end part of the pillar member 121 via a linking shaft 123 extending in X-direction. In this state, the beam member 122 is rotatably supported within a plane (vertical plane) orthogonal to X-direction. Accordingly, the pressing mechanism 120 has a seesaw structure in which the beam member 122 is supported with the linking shaft 123 as a fulcrum.

In the pressing mechanism 120, the beam member 122 is supported in a state of extending along Y-direction or being inclined within a range of several tens of degrees (for example, 30°) or less with respect to Y-direction. In the following description, the end part of the beam member 122 facing +Y direction is referred to as a first end part 122a, and the end part facing −Y direction is referred to as a second end part 122b.

The lower end part of the first end part 122a of the beam member 122 contacts or is close to the upper end part of the cylinder rod 112 in a state where the air cylinder device 110 does not operate. Also, the lower end part of the second end part 122b of the beam member 122 contacts or is close to the upper end part of a load transmission member 130 to be described later in a state where the air cylinder device 110 does not operate.

With such configuration, when the air cylinder device 110 operates to generate a force directed upward (+Z direction) in the cylinder rod 112, the first end part 122a is pressed upward (+Z direction) by the cylinder rod 112. At this time, the beam member 122 rotates with the linking shaft 123 as a reference. Accordingly, the second end part 122b presses the load transmission member 130 downward (−Z direction).

The load transmission member 130 is configured with, for example, a single component formed of a material having high rigidity. The load transmission member 130 of this example is a member showing an inverted L-shape when viewed in Y-direction as shown in FIG. 7, and has a portion extending in X-direction and a portion extending in Z-direction. In the following description, a portion of the load transmission member 130 extending in X-direction is referred to as a load reception part 131. Also, a portion of the load transmission member 130 extending in Z-direction is referred to as a lifting support part 132.

Here, in the brush support part 42 at the tip of the brush arm 41, a through hole 103 is formed in the base member 101 to communicate the internal space of the housing H with a space below the housing H. The brush device 80 is supported by the brush support shaft 81 at a position below the base member 101. The brush support shaft 81 is provided to extend in Z-direction through the through hole 103 of the base member 101. Accordingly, the upper part of the brush support shaft 81 is positioned inside the brush arm 41, and the lower part of the brush support shaft 81 is positioned below the base member 101.

The load transmission member 130 is disposed above the through hole 103 so that a portion of the load reception part 131 overlaps with the through hole 103 in Z-direction. An upper bearing part 420 is provided in a portion of the load reception part 131.

The upper bearing part 420 connects one end part (upper end part) of the brush support shaft 81 to the load transmission member 130, so as to be rotatable around its axis and immovable in Z-direction relative to the load transmission member 130.

Inside the housing H, a self-weight offset mechanism 490 is attached to the brush support shaft 81 to rotate together with the brush support shaft 81. The self-weight offset mechanism 490 includes a coil spring extending in Z-direction, and an upper end part is fixed to a portion of the brush support shaft 81. Meanwhile, a lower end part of the self-weight offset mechanism 490 is not fixed to the brush support shaft 81 in Z-direction.

A pulley 521 is further attached to the brush support shaft 81 to rotate together with the brush support shaft 81. The pulley 521, similar to the lower end part of the self-weight offset mechanism 490, is not fixed to the brush support shaft 81 in Z-direction.

A lower bearing part 410 is provided in a portion of the base member 101 where the through hole 103 is formed. The lower bearing part 410 supports the pulley 521 on the base member 101 to be rotatable around the axis of the brush support shaft 81. Also, the lower bearing part 410 supports the pulley 521 on the base member 101 to be immovable in Z-direction relative to the base member 101 while allowing movement of the brush support shaft 81 in Z-direction.

As described above, the upper end part of the self-weight offset mechanism 490 is fixed to a portion of the brush support shaft 81. In this state, the lower end part of the self-weight offset mechanism 490 is supported on the base member 101 via the pulley 521 and the lower bearing part 410 in Z-direction. Accordingly, a load corresponding to the total weight of the brush device 80, the brush support shaft 81, and the load transmission member 130 that are integrally connected in Z-direction acts on the coil spring of the self-weight offset mechanism 490. In the following description, the load corresponding to the total weight of the brush device 80, the brush support shaft 81, and the load transmission member 130 is referred to as brush self-weight.

The coil spring of the self-weight offset mechanism 490 is selected to obtain an elastic force corresponding to the brush self-weight. Also, the coil spring of the self-weight offset mechanism 490 is selected so that a reaction force according to the expansion and contraction of the coil spring does not affect the transmission accuracy of the load given from the air cylinder device 110 to the brush device 80. By appropriately selecting the coil spring, in the brush arm 41, a configuration including the brush device 80, the brush support shaft 81, and the load transmission member 130 is supported on the base member 101 to float at a predetermined height position.

On the upper surface of the base member 101, a pillar member 140 is provided at a position shifted in +X direction from the lower bearing part 410. The pillar member 140 extends a certain length upward (+Z direction) from the upper surface of the base member 101. The pillar member 140 is connected to the lifting support part 132 of the load transmission member 130 via a linear guide 200.

The linear guide 200 includes a linear rail 210 and a slider 220. The slider 220 is attached to the rail 210 to be movable in a direction in which the rail 210 extends and immovable in directions other than the direction in which the rail 210 extends.

In the embodiment, the rail 210 is fixed to the pillar member 140 to extend in Z-direction. Meanwhile, the slider 220 is fixed to the lifting support part 132 of the load transmission member 130. Accordingly, the linear guide 200 restricts the movement direction of the load transmission member 130 to Z-direction.

The pulley 521 provided on the brush support shaft 81 is used to rotate the brush device 80 around a Z-direction axis, that is, to rotate the brush device 80 on its own axis. By rotating the brush device 80 on its own axis during the cleaning process of the substrate W, the efficiency of the cleaning process of the substrate W is improved. To rotate the brush device 80 on its own axis, a motor 510, a pulley 522, and a belt 523 are provided in the brush arm 41, in addition to the pulley 521. Also, a motor drive part 520 for operating the motor 510 is provided outside the brush arm 41.

Specifically, as shown in FIG. 4, the motor 510 is provided at a position on the upper surface of the base member 101 between the load transmission member 130 and the pillar member 121 in Y-direction and shifted in +X direction from the beam member 122.

As shown in FIG. 6, the motor 510 is fixed on the upper surface of the base member 101 by a motor fixing piece 511, so that the rotation shaft thereof protrudes downward. The pulley 522 is attached to a tip part of the rotation shaft of the motor 510. The pulley 522 is fixed at the same height position as the pulley 521. The belt 523 is stretched between the two pulleys 521 and 522.

The motor drive part 520 is connected to the motor 510. The motor drive part 520 supplies a current to the motor 510 based on the control of the control part 900 to be described later, and rotates the motor 510.

During the operation of the motor 510, a rotational force generated by the motor 510 is transmitted from the rotation shaft of the motor 510 to the brush support shaft 81 through the pulley 522, the belt 523, and the pulley 521. As described above, the pulley 521 is not fixed to the brush support shaft 81 in Z-direction. Therefore, even in the case where the brush support shaft 81 moves in Z-direction, the movement does not affect the transmission of the rotational force from the motor 510 to the brush support shaft 81.

The force generated in the cylinder rod 112 during the operation of the air cylinder device 110 is converted by the pressing mechanism 120 into a pressing force that presses the load transmission member 130 downward (in −Z direction). The pressing force in Z-direction acting on the load transmission member 130 is transmitted to the brush device 80 through the load transmission member 130, the upper bearing part 420, and the brush support shaft 81.

The pressing force of the brush device 80 against the substrate W differs according to the type of the substrate W as the processing target and the cleaning method. Therefore, the pressing force of the brush device 80 against the substrate W is set in advance for each substrate W. In the following description, the pressing force of the brush device 80 set for each substrate W is referred to as a set pressing force.

During cleaning of one substrate W, when the pressing force acting from the brush device 80 on the one substrate W is largely shifted from the set pressing force, the desired cleaning process cannot be performed. Therefore, the brush arm 41 is provided with the load sensor 310. Based on the detection result of the load sensor 310, the actual pressing force (load) transmitted to the brush device 80 during operation of the air cylinder device 110 is detected.

Specifically, in the embodiment, as the load sensor 310, for example, a Roberval-type load cell is used. The load sensor 310 is fixed on the base member 101 via a sensor base 320 at a position shifted in −X direction from the motor 510, as shown in FIG. 5. A plate-shaped contact member 311 is attached to a portion of the load sensor 310. The contact member 311 is positioned such that the tip end portion thereof is located below the load reception part 131 of the load transmission member 130.

As shown in FIG. 7, in a state where the air cylinder device 110 does not operate, a relatively large gap is formed between the load reception part 131 and the contact member 311. Therefore, in a state where the pressing force from the air cylinder device 110 does not act on the load transmission member 130, the load sensor 310 does not detect the pressing force acting on the load transmission member 130. Meanwhile, the air cylinder device 110 operates, the load transmission member 130 is pressed downward, and the lower end part of the load reception part 131 contacts the contact member 31. Accordingly, the load sensor 310 detects the pressing force acting on the load transmission member 130.

4. Brush Pressing Force Adjustment Process and Cleaning Process Of Substrate W

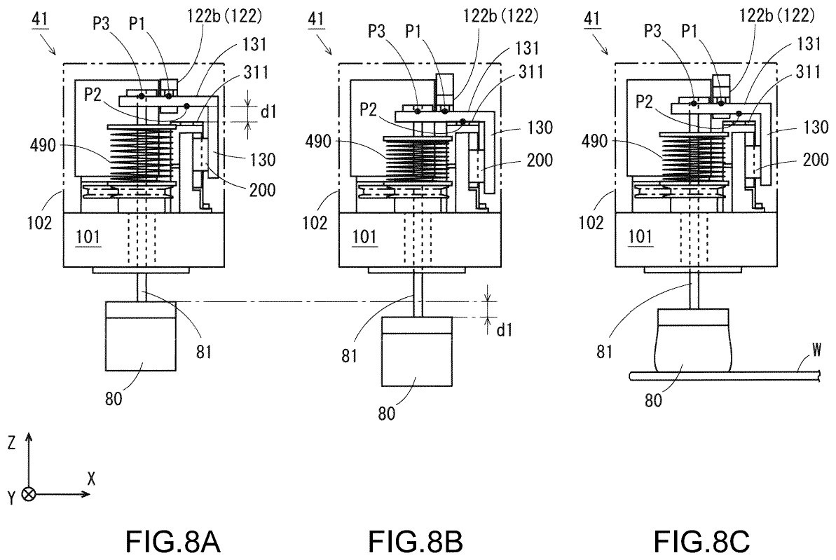

FIGS. 8A to 8C are diagrams for describing the brush pressing force adjustment process. FIG. 8A shows a schematic end view of one end of the brush arm 41 in a stop state in an end surface before the brush pressing force adjustment process. Also, FIG. 8B shows a schematic end view of one end of the brush arm 41 during the brush pressing force adjustment process. Furthermore, FIG. 8C shows a schematic end view of one end of the brush arm 41 during the cleaning process of the substrate W. In each schematic end view, the cover member 102 is shown by a dash-double-dot line, similarly to the schematic end view of FIG. 7.

Here, a portion of the load transmission member 130 that opposes the second end part 122b of the beam member 122 in Z-direction is referred to as a first force transmission point P1. Also, a portion of the load transmission member 130 that opposes the contact member 311 connected to the load sensor 310 in Z-direction is referred to as a second force transmission point P2. Furthermore, a portion of the load transmission member 130 where the brush support shaft 81 is connected (attachment part of the upper bearing part 420) is referred to as a third force transmission point P3.

In the stop state, the air cylinder device 110 of FIG. 4 is assumed to be not operating. Accordingly, the first force transmission point P1 of the load transmission member 130 does not receive the pressing force directed downward from the second end part 122b of the beam member 122. At this time, as shown in FIG. 8A, the brush device 80, the brush support shaft 81, and the load transmission member 130 connected to each other are supported by the elastic force of the coil spring of the self-weight offset mechanism 490 in a state where the second force transmission point P2 is separated from the contact member 311 by a distance d1. In the embodiment, the distance d1 is, for example, about 5 cm.

When the brush pressing force adjustment process is started, the air cylinder device 110 of FIG. 4 is driven under a predetermined operating condition based on the set pressing force. Accordingly, the first force transmission point P1 of the load transmission member 130 is pressed downward, and as shown in FIG. 8B, the brush device 80, the brush support shaft 81, and the load transmission member 130 connected to each other descend. Also, the second force transmission point P2 of the load transmission member 130 contacts the contact member 311. Accordingly, the descent of the brush device 80, the brush support shaft 81, and the load transmission member 130 stops. At this time, the brush device 80 is positioned in the distance d1 below the height position in the stop state.

In this state, the pressing force acting from the second end part 122b of the beam member 122 to the first force transmission point P1 of the load transmission member 130 is detected by the load sensor 310 of FIG. 4 as the actual pressing force (load) transmitted to the brush device 80.

The control part 900 of FIG. 1 changes the operating condition of the air cylinder device 110 so that the detection result of the load sensor 310 matches or substantially matches the set pressing force. That is, the control part 900 performs feedback control of the air cylinder drive part 113 of FIG. 4. Thereafter, with the detection result of the load sensor 310 matching or substantially matching the set pressing force, the brush pressing force adjustment process ends.

Then, during the cleaning process of the substrate W, the brush arm 41 is moved in a state where the air cylinder device 110 operates according to the adjusted operating condition, and the brush device 80 is pressed against the upper surface of the substrate W. At this time, the set pressing force acting on the second force transmission point P2 of the load transmission member 130 acts on the substrate W from the third force transmission point P3 of the load transmission member 130 through the brush support shaft 81 and the brush device 80. In this manner, the brush device 80 is pressed against the substrate W with the set pressing force. Accordingly, the load transmission member 130 rises and is disengaged from the contact member 311, and the pressing force acting on the contact member 311 is released. Also, according to the positional relationship between the brush arm 41 and the substrate W, as shown in FIG. 8C, the second force transmission point P2 of the load transmission member 130 and the contact member 311 are separated.

### 5. Moment Acting on Linear Guide 200

As described above, in the brush arm 41, the linear guide 200 is used to restrict the movement direction of the load transmission member 130 pressed by the beam member 122 to Z-direction. The linear guide 200 has a configuration in which the slider 220 is attached to the rail 210.

The case where a downward pressing force acts on the first force transmission point P1 of the load transmission member 130 is assumed. In this case, a moment may be generated in the linear guide 200. Depending on the direction of the moment generated in the linear guide 200, fluctuation may occur in the connection state between the rail 210 and the slider 220. Specifically, a shift may occur in the positional relationship between the rail 210 and the slider 220.

Such occurrence of the fluctuation in the connection state between the rail 210 and the slider 220 spreads the pressing force applied from the beam member 122 to the load transmission member 130 in directions other than Z-direction. When the pressing force applied to the load transmission member 130 is spread in directions other than Z-direction, the pressing force acting on the load transmission member 130 cannot be accurately detected during the brush pressing force adjustment process.

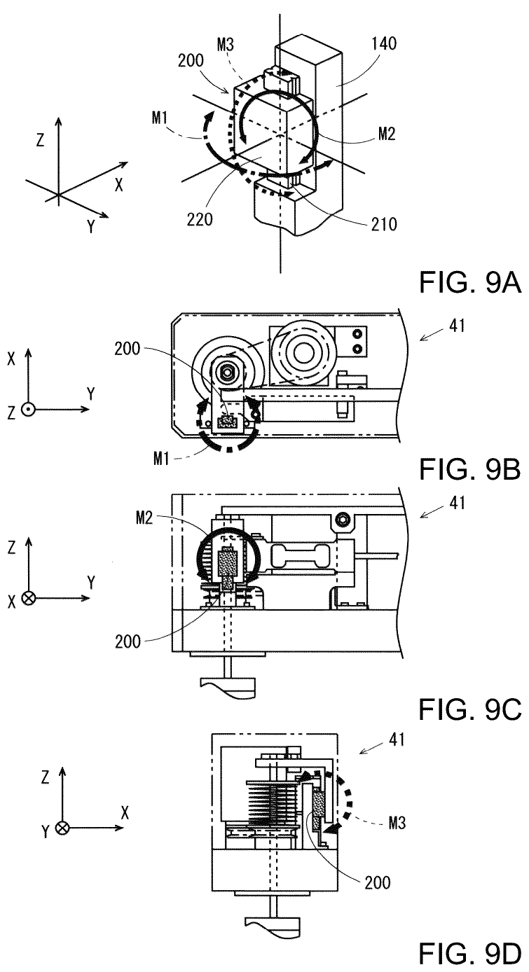

FIGS. 9A to 9D are is diagrams for defining a moment that may be generated in the linear guide 200. FIG. 9A is a perspective view of the appearances of the pillar member 140 and the linear guide 200. Also, FIG. 9B is a schematic plan view of a portion of the brush arm 41, FIG. 9C is a schematic side view of one side of a portion of the brush arm 41, and FIG. 9D is a schematic end view of one end of the brush arm 41. In each of the views in the second part, the third part, and the fourth part, a dot pattern is applied to the linear guide 200 for the ease of identification of the linear guide 200.

As shown by the arrows in thick dash-dot lines in FIGS. 9A and 9B, a moment around Z-direction axis may be generated in the linear guide 200. This moment is referred to as a first moment M1. As shown by arrows in thick solid lines in FIGS. 9A and 9C, a moment around X-direction axis may be generated in the linear guide 200. This moment is referred to as a second moment M2. As shown by arrows in thick dotted line in FIGS. 9A and 9D, a moment around Y-direction axis may be generated in the linear guide 200. This moment is referred to as a third moment M3.

The generation of the first moment M1 during the brush pressing force adjustment process is described. During the brush pressing force adjustment process, the brush device 80 does not contact the substrate W. Also, no pressing force directed in X-direction and Y-direction is applied to the load transmission member 130. Therefore, the first moment M1 does not occur in the linear guide 200 during the brush pressing force adjustment process.

Next, the generation of the second moment M2 during the brush pressing force adjustment process is described. As shown in FIG. 4, the first force transmission point P1, the second force transmission point P2, and the linear guide 200 overlap with a virtual line L11 extending in X-direction when viewed in a plan view. According to this positional relationship, even in the case where the second force transmission point P2 of the load transmission member 130 contacts the contact member 311 of the load sensor 310 during the brush pressing force adjustment process, the second moment M2 does not occur.

Next, the generation of the third moment M3 during the brush pressing force adjustment process is described. As shown in FIG. 4, the first force transmission point P1 and the second force transmission point P2 are separated from each other when viewed in a plan view. Also, a pressing force directed in −Z direction acts on the first force transmission point P1 of the load transmission member 130, but a force directed in +Z direction acts on the second force transmission point P2 of the load transmission member 130. Therefore, the third moment M3 is generated in the linear guide 200.

Thus, in the brush arm 41 according to the embodiment, the first moment M1 and the second moment M2 do not occur during the brush pressing force adjustment process. Accordingly, the connection state between the rail 210 and the slider 220 is prevented from fluctuating due to the generation of the first moment M1 and the second moment M2 in the linear guide 200. Therefore, the divergence between the pressing force applied to the load transmission member 130 by the air cylinder device 110 and the value of the pressing force detected by the load sensor 310 during the brush pressing force adjustment process is suppressed.

As a result, the reliability of the detection result of the load sensor 310 in the brush pressing force adjustment process is improved, and the accuracy of cleaning of the substrate W by using the brush device 80 is improved.

As shown in FIG. 4, when viewed in a plan view, the distance between the first force transmission point P1 and the second force transmission point P2 is smaller than the distance between the first force transmission point P1 and the third force transmission point P3. Also, when viewed in a plan view, the distance between the first force transmission point P1 and the second force transmission point P2 is smaller than ⅓ of the length of the load transmission member 130 in X-direction. That is, when viewed in a plan view, the distance between the first force transmission point P1 and the second force transmission point P2 is relatively small. Accordingly, the third moment M3 generated in the linear guide 200 is prevented from becoming large.

### 6. Structure and Attachment Direction of Linear Guide 200

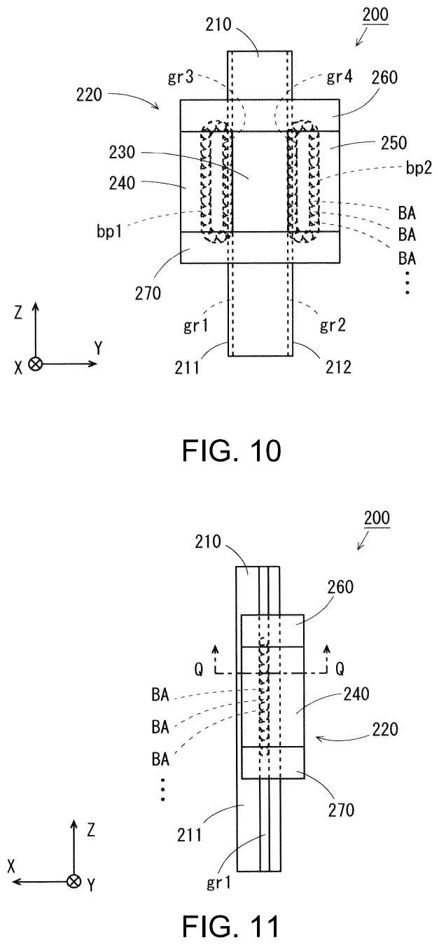

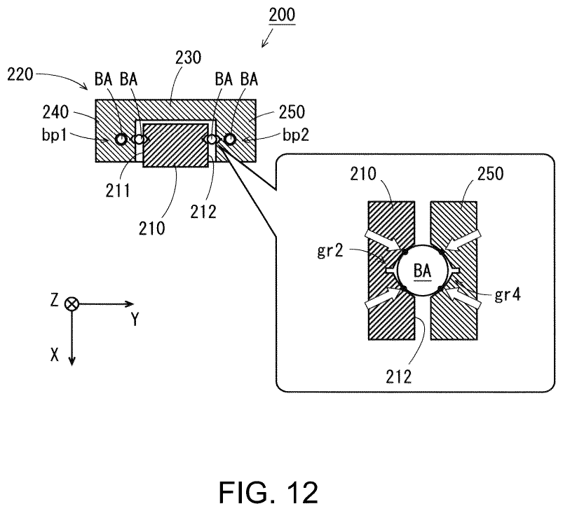

FIG. 10 is a plan view of the linear guide 200 built in the brush arm 41 of FIG. 1. FIG. 11 is a schematic side view of one side of the linear guide 200 of FIG. 10 when viewed in +Y direction. FIG. 12 is a cross-sectional view taken along a line Q-Q of FIG. 11. As shown in FIG. 10 to FIG. 12, the linear guide 200 according to the embodiment includes multiple balls BA in addition to the rail 210 and the slider 220 described above. Details of each member will be described.

As shown in FIG. 10, the rail 210 is provided to extend linearly in Z-direction and has a first side part 211 and a second side part 212 that face each other in directions opposite to each other. Specifically, the first side part 211 faces −Y direction, and the second side part 212 faces +Y direction. Guide grooves gr1 and gr2 extending in Z-direction are formed in each of the first side part 211 and the second side part 212.

The slider 220 includes a rail overlap part 230, a first attachment part 240, a second attachment part 250, and a pair of end caps 260 and 270. The rail overlap part 230, the first attachment part 240, and the second attachment part 250 are configured as a single member formed integrally.

In the following description, the single member formed by the rail overlap part 230, the first attachment part 240, and the second attachment part 250 is appropriately referred to as a slider body. The end caps 260 and 270 are attached to one end part and the other end part of the slider body in Z-direction, respectively.

As shown in FIG. 12, the cross-section of the slider body orthogonal to Z-direction is formed in an inverted U-shape to be able to sandwich a portion of the rail 210. The first attachment part 240 corresponds to the first side part 211 of the rail 210, and the second attachment part 250 is formed to correspond to the second side part 212 of the rail 210. Accordingly, in the state where the slider 220 is attached to the rail 210, a portion of the first attachment part 240 opposes the first side part 211. Also, a portion of the second attachment part 250 opposes the second side part 212. The rail overlap part 230 overlaps the rail 210 in X-direction.

In the portion of the first attachment part 240 that opposes the first side part 211 of the rail 210, a guide groove gr3 extending in Z-direction is formed. Accordingly, a space extending in Z-direction is formed between the guide groove gr1 of the first side part 211 and the guide groove gr3 of the first attachment part 240. Also, in the first attachment part 240, a through hole bp1 that penetrates the first attachment part 240 in Z-direction is formed in the vicinity of the guide groove gr3.

In the portion of the second attachment part 250 that opposes the second side part 212 of the rail 210, a guide groove gr4 extending in Z-direction is formed. Accordingly, a space extending in Z-direction is formed between the guide groove gr2 of the second side part 212 and the guide groove gr4 of the second attachment part 250. Also, in the second attachment part 250, a through hole bp2 that penetrates the second attachment part 250 in Z-direction is formed in the vicinity of the guide groove gr4.

As shown in FIG. 10, a guide path that connects the internal space of the through hole bp1 formed in the first attachment part 240 and the space formed by the guide grooves gr1 and gr3 is formed in the end cap 260. Also, a guide path that connects the internal space of the through hole bp2 formed in the second attachment part 250 and the space formed by the guide grooves gr2 and gr4 is formed in the end cap 260. Also, like the end cap 260, a guide path that connects the internal space of the through hole bp1 and the space formed by the guide grooves gr1 and gr3 is also formed in the end gap 270. Also, a guide path that connects the internal space of the through hole bp2 and the space formed by the guide grooves gr2 and gr4 is formed in the end gap 270.

The guide groove gr1 of the rail 210, the guide groove gr3 of the first attachment part 240, the through hole bp1 of the first attachment part 240, and the guide paths of the end caps 260 and 270 form one circulation passage in which multiple balls BA are able to circulate and move. Also, the guide groove gr2 of the rail 210, the guide groove gr4 of the second attachment part 250, the through hole bp2 of the second attachment part 250, and the guide paths of the end caps 260 and 270 form another circulation passage in which multiple balls BA can circulate and move. Each circulation passage is filled with the balls BA.

In the linear guide 200 having the configuration, through the balls BA rolling and moving within each circulation passage, the slider 220 moves smoothly along the rail 210.

Here, as shown in the enlarged portion of FIG. 12, the ball BA positioned between the rail 210 and the slider body generally contacts the groove (gr2) of the rail 210 at two points. Furthermore, the ball BA also generally contacts the groove (gr4) of the slider body at two points. That is, the ball BA is supported at four points with respect to the rail 210 and the slider body, as indicated by the four white arrows in the enlarged portion of FIG. 12.

In a linear guide including balls BA, it is known that a difference occurs in the magnitude of differential slip generated in each ball provided between the rail and the slider, depending on whether the ball makes two-point contact or four-point contact with the rail and slider. Specifically, it is known that the differential slip generated in a ball making two-point contact with the rail and the slider is smaller than the differential slip generated in a ball making four-point contact with the rail and the slider.

Considering this point, in the case where a force in Y-direction acts between the rail 210 and the slider body, causing some of the balls BA to be firmly sandwiched at four points, it is considered that a relatively large differential slip occurs in the balls BA. That is, it is considered that a large fluctuation is likely to occur in the connection state between the rail 210 and the slider 220.

Meanwhile, the case as follows is assumed: a shear force is generated between the rail 210 and the slider body that sandwich some of the balls BA due to the acting of the force in X-direction between the rail 210 and the slider body. In this case, some of the balls BA are substantially supported at two points by the rail 210 and the slider body that attempt to move relatively in X-direction. Accordingly, in the case where a force in X-direction acts between the rail 210 and the slider body, the differential slip generated in each ball BA is considered to be smaller than the case where a force in Y-direction acts between the rail 210 and the slider body. That is, it is considered that a large fluctuation is unlikely to occur in the connection state between the rail 210 and the slider 220.

Here, in the linear guide 200, in the case where the second moment M2 of FIGS. 9A to 9D is generated, a force in Y-direction acts between the rail 210 and the slider body. Also, in the linear guide 200, in the case where the first moment M1 and the second moment M2 of FIGS. 9A to 9D are generated, a force in X-direction acts between the rail 210 and the slider body.

As described above, in the brush arm 41 according to the embodiment, the first moment M1 and the second moment M2 are not generated during the brush pressing force adjustment process due to the positional relationship of the first force transmission point P1, the second force transmission point P2, and the linear guide 200. Therefore, no force in Y-direction acts between the rail 210 and the slider body in the linear guide 200. Accordingly, it is considered that large fluctuations are unlikely to occur in the connection state between the rail 210 and the slider 220 during the brush pressing force adjustment process. That is, it is considered that the load applied to the load transmission member 130 can be detected with high accuracy during the brush pressing force adjustment process.

The inventors conducted a pressing force detection experiment described below to confirm whether the above consideration is correct. First, the inventors prepared the brush arm 41 of FIG. 4 as the brush arm 41 of the example. Also, the inventors operated the air cylinder device 110 intermittently multiple times under an operating condition corresponding to a set pressing force of 250 g. Furthermore, the inventors recorded the pressing force (load) detected by the load sensor 310.

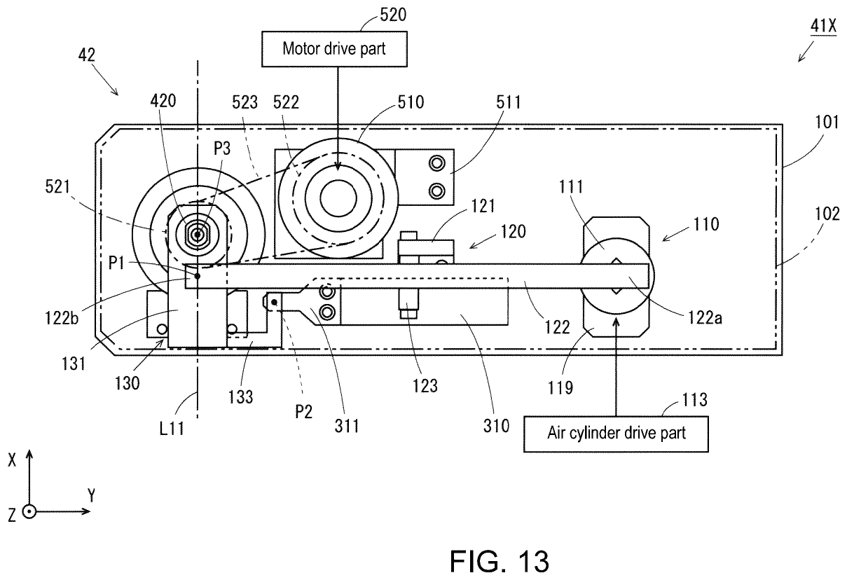

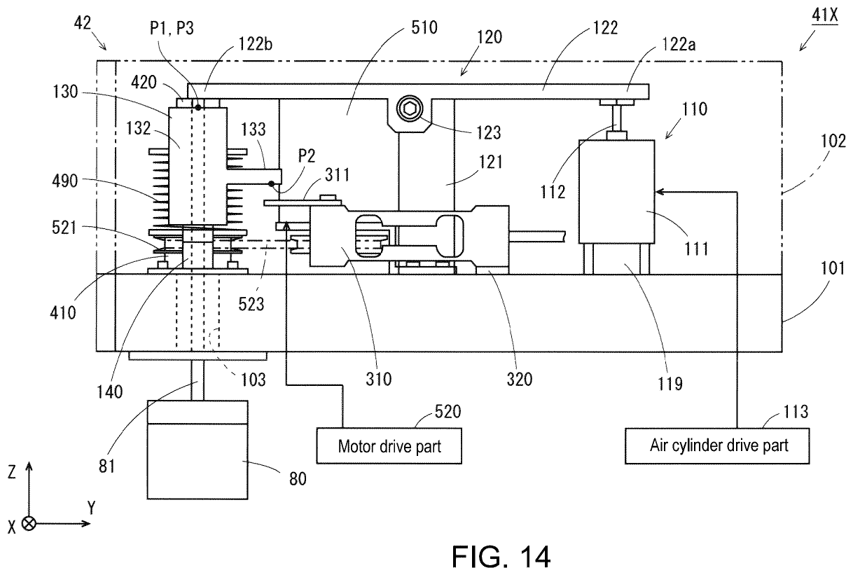

Also, the inventors prepared a brush arm of a comparative example that differs in some configurations from the brush arm 41 of the example. FIG. 13 is a schematic plan view of the brush arm according to the comparative example as viewed in −Z direction. FIG. 14 is a schematic view of one side of the brush arm 41X of FIG. 13 when viewed in +X direction.

In a brush arm 41X according to the comparative example, the configuration of the load transmission member 130 differs from the configuration of the embodiment. As shown in FIG. 13 and FIG. 14, the load transmission member 130 of this example has a supported piece 133 in addition to the load reception part 131 and the lifting support part 132. The supported piece 133 is formed to extend a fixed distance in +Y direction from a portion of the lifting support part 132, bend, and extend a fixed distance in +X direction. The contact member 311 of the load sensor 310 is disposed below the supported piece 133 to overlap with the tip part of the supported piece 133 in a plan view.

With such a configuration, in the brush arm 41X according to the comparative example, when the load transmission member 130 is pressed and lowered, the supported piece 133 contacts and is supported by the contact member 311. Accordingly, the pressing force applied to the load transmission member 130 is detected by the load sensor 310. Therefore, in the brush arm 41X, the portion of the supported piece 133 of the load transmission member 130 that faces the contact member 311 in Z-direction becomes the second force transmission point P2.

In this case, the second force transmission point P2 deviates from the virtual line L11 when viewed in a plan view (see FIG. 13). Therefore, when the pressing force applied to the load transmission member 130 is detected by the load sensor 310, the second moment M2 around the virtual line L11 is generated (see FIGS. 9A to 9D).

The inventors used the brush arm 41X of the comparative example to operate the air cylinder device 110 intermittently multiple times under an operating condition corresponding to the set pressing force of 250 g. Furthermore, the inventors recorded the pressing force (load) detected by the load sensor 310.

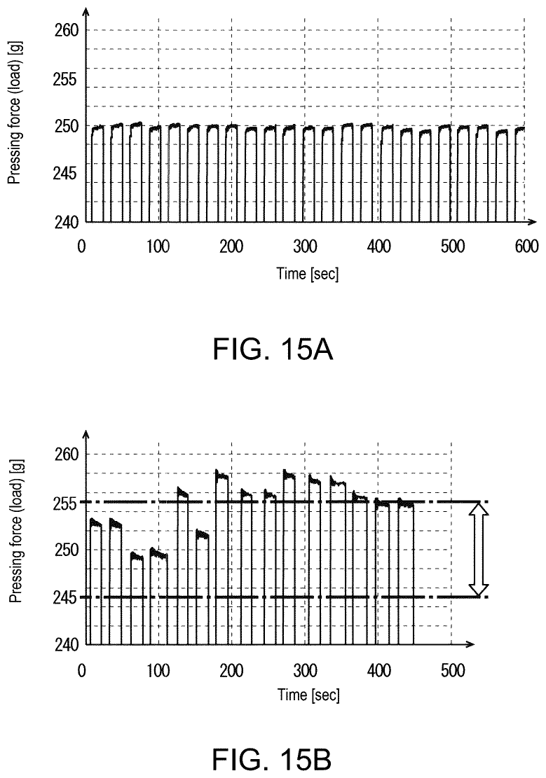

FIGS. 15A and 15B are diagrams showing pressing force detection experiment results. FIG. 15A shows the pressing force detection experiment results according to the embodiment in a graph. Also, FIG. 15B shows the pressing force detection experiment results according to the comparative example in a graph. In each graph, the vertical axis represents the pressing force (load) detected by the load sensor 310, and the horizontal axis represents time.

As shown in FIG. 15A, according to the pressing force detection experiment results of the embodiment, a pressing force of approximately 250 g was detected each time the air cylinder device 110 operated. Also, almost no variation was observed in the multiple pressing forces detected over multiple times (23 times in this example).

Meanwhile, according to the pressing force detection experiment results of the comparative example, the value of the detected pressing force fluctuated greatly each time the air cylinder device 110 operated. Also, there were cases where no pressing force was detected even though the air cylinder device 110 was operating. As a result, the pressing forces detected over multiple times (15 times in this example) showed large variations exceeding a range of 10 g around 250 g (the range of the white arrows in FIG. 15B).

From these results, it is confirmed that the consideration that, with the brush arm 41 of FIG. 4, the load applied to the load transmission member 130 can be detected with high accuracy during the brush pressing force adjustment process is correct.

### 7. Control System of Substrate Cleaning Device 1

The control system of the substrate cleaning device 1 will be described together with the configuration of the control part 900 of FIG. 1. FIG. 16 is a block diagram showing the configuration of the control system of the substrate cleaning device 1 in FIG. 1. As shown in FIG. 16, the control part 900 includes a central processing unit (CPU) 901, a random access memory (RAM) 902, a read only memory (ROM) 903, and a memory device 904.

The RAM 902 is used as a working area for the CPU 901. The ROM 903 stores system programs. The memory device 904 includes a storage medium such as a hard disk or a semiconductor memory, and stores a substrate cleaning program for performing a cleaning process of the substrate W and a load adjustment program for performing a brush pressing force adjustment process. Furthermore, the memory device 904 stores the set pressing force and the operating condition of the air cylinder device 110 determined based on the set pressing force.

The substrate cleaning program and the load adjustment program may be provided in a state of being stored in a recording medium such as a CD-ROM 909, and installed in the ROM 903 or the memory device 904. Alternatively, the substrate cleaning program and the load adjustment program may be distributed from a server external to the substrate cleaning device 1 via a communication network, and installed in the ROM 903 or the memory device 904.

With the CPU 901 executing the substrate cleaning program and the load adjustment program, the operation of each part of the substrate cleaning device 1 is controlled. Specifically, the control part 900 controls the substrate holding drive part 13. Accordingly, the control part 900 causes the substrate holding device 10 to hold the substrate W carried into the substrate cleaning device 1 by transitioning the state of the holding pins 12 from the release state to the holding state. Also, the control part 900 transitions the state of the holding pins 12 from the holding state to the release state to carry out the substrate W from the substrate cleaning device 1. Furthermore, the control part 900 controls the substrate rotation drive part 14. Accordingly, during the cleaning process of the substrate W, the substrate W held by the substrate holding device 10 rotates.

Also, the control part 900 controls the cup lifting drive part 22. Accordingly, during the cleaning process of the substrate W, the cup body 21 of FIG. 1 moves between the cup upper position and the cup lower position. Also, the control part 900 controls the fluid supply system 32. Accordingly, during the cleaning process of the substrate W, the cleaning liquid is discharged from the fluid nozzle 31 of FIG. 1 to the substrate W.

Also, the control part 900 controls the arm horizontal drive part 45 and the arm lifting drive part 46. Accordingly, during the cleaning process of the substrate W, the brush arm 41 moves within the chamber CH.

In the embodiment, each of the arm horizontal drive part 45 and the arm lifting drive part 46 includes a motor with a built-in encoder as a power source. Therefore, the control part 900 acquires the positions of the brush arm 41 in X-direction and Z-direction based on the outputs of the encoders of the arm horizontal drive part 45 and the arm lifting drive part 46. Accordingly, in the control part 900, the positional relationship between the brush arm 41 and the floor surface CHB of the chamber CH is grasped. Alternatively, the positional relationship between the brush arm 41 and the substrate W held by the substrate holding device 10 is grasped.

Also, the control part 900 controls the motor drive part 520. Accordingly, the control part 900 causes the brush device 80 to rotate at a predetermined rotation speed by operating the motor 510 built in the brush arm 41 during the cleaning process of the substrate W.

Also, the control part 900 controls the air cylinder drive part 113 based on the set pressing force stored in the memory device 904 and the operating condition of the air cylinder device 110 during the brush pressing force adjustment process. Furthermore, the control part 900 adjusts the operating condition of the air cylinder device 110 based on the detection result of the pressing force at the load sensor 310 during the brush pressing force adjustment process. Accordingly, the brush device 80 is pressed against each part of the upper surface of the substrate W with a predetermined set pressing force during the cleaning process of the substrate W.

As shown in FIG. 16, the substrate cleaning device 1 further includes an operation part 990. The operation part 990 includes a keyboard and a pointing device, and is configured to be operable by a user. The user can input various information such as the set pressing force and the corresponding operating condition of the air cylinder device 110 by operating the operation part 990. When various information is input, the control part 900 stores the input information in the memory device 904.

### 8. Flow of Brush Pressing Force Adjustment Process

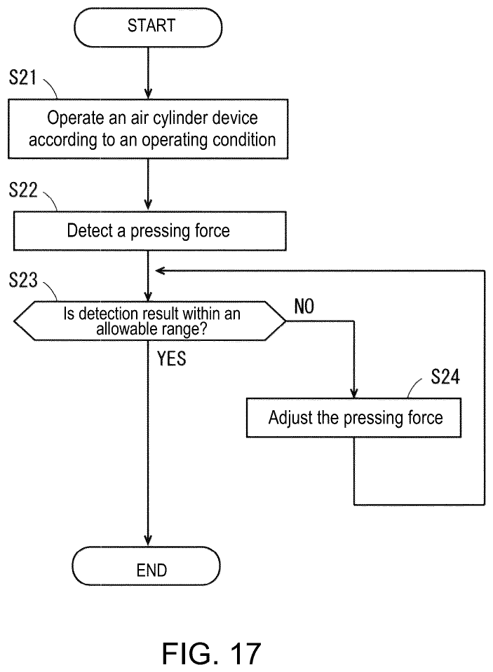

FIG. 17 is a flowchart of the brush pressing force adjustment process. As shown in the example of FIG. 2, the brush pressing force adjustment process is performed after the substrate W is carried into the chamber CH of the substrate cleaning device 1 and before the cleaning process of the substrate W is started.

Here, it is assumed that the memory device 904 of FIG. 16 stores an allowable range corresponding to the set pressing force. The allowable range is a range of a predetermined width centered on the value of the set pressing force. For example, in the case where the set pressing force is 250 g, the allowable range is set to a range of 10 g centered on 250 g (i.e., 245 g or more and 255 g or less).

When the brush pressing force adjustment process is started, the control part 900 controls the air cylinder drive part 113 to operate the air cylinder device 110 according to the preset operating condition (Step S21).

Next, the control part 900 detects the pressing force (load) applied to the load transmission member 130 based on the output signal of the load sensor 310 (Step S22). After that, the control part 900 determines whether the detection result is within the allowable range (Step S23). In the case where the detection result is within the allowable range, the control part 900 ends the process.

On the other hand, in the case where the detection result is not within the allowable range, the control part 900 adjusts the operating condition so that the detection result approaches the set pressing force, and adjusts the pressing force by controlling the air cylinder drive part 113 (Step S24). After that, the process proceeds to Step S23.

### 9. Substrate Processing Device Including Substrate Cleaning Device 1

FIG. 18 is a schematic plan view showing an example of a substrate processing device including the substrate cleaning device 1 of FIG. 1. As shown in FIG. 18, a substrate processing device 800 of this example has an indexer block 801 and a processing block 802. The indexer block 801 and the processing block 802 are provided adjacent to each other.

The indexer block 801 includes multiple (four in this example) carrier mounting stages 810 and a transport part 820. The carrier mounting stages 810 are connected to the transport part 820 and are arranged in a row at intervals. On each carrier mounting stage 810, a carrier C that stores multiple substrates W is mounted.

The transport part 820 is provided with an indexer robot 831 and a control device 832. The indexer robot 831 includes multiple (for example, four) hands and is configured to be capable of holding and transporting the substrate W. The control device 832 includes a CPU and a memory or a microcomputer, and controls each component in the substrate processing device 800.

As shown in FIG. 18, the processing block 802 includes cleaning parts 841, 842 and a transport part 843. The cleaning part 841, the transport part 843, and the cleaning part 842 are arranged adjacent to the transport part 820 and aligned in this order. In each of the cleaning parts 841, 842, multiple (for example, four) substrate cleaning devices 1 are stacked vertically. The substrate cleaning devices 1 are the substrate cleaning device 1 of FIG. 1. That is, in the substrate processing device 800 of FIG. 18, the substrate cleaning device 1 of FIG. 1 is provided as one processing unit forming the substrate processing device 800.

The transport part 843 is provided with a main robot 844. The main robot 844 includes multiple (for example, four) hands and is configured to be capable of holding and transporting the substrate W.

Between the indexer block 801 and the processing block 802, multiple substrate mounting parts PASS for transferring the substrate W between the indexer robot 831 and the main robot 844 are stacked in the upper-lower direction.

In the substrate processing device 800, the indexer robot 831 takes out an unprocessed substrate W from any carrier C among multiple carriers C mounted on multiple carrier mounting stages 810. Also, the indexer robot 831 mounts the unprocessed substrate W on any of the substrate mounting parts PASS. Furthermore, the indexer robot 831 receives a processed substrate W mounted on any of the multiple substrate mounting parts PASS and accommodates the processed substrate W in an empty carrier C.

The main robot 844 receives multiple unprocessed substrates W mounted on multiple substrate mounting parts PASS, respectively. Also, the main robot 844 carries the unprocessed substrates W into multiple substrate cleaning devices 1 of the cleaning parts 841, 842, respectively. Furthermore, the main robot 844 carries out multiple processed substrates W from the substrate cleaning devices 1, respectively. Also, the main robot 844 mounts the processed substrate W on any of the substrate mounting parts PASS.

Each substrate cleaning device 1 of the cleaning parts 841, 842 cleans the upper surface of the substrate W that is carried in. In each substrate cleaning device 1, the upper surface of the substrate W is appropriately cleaned with the set pressing force. Accordingly, the occurrence of cleaning defects of the substrate W is suppressed.

### 10. Effects

(a) In the substrate cleaning device 1, with the air cylinder device 110 applying a pressing force to the first force transmission point P1 of the load transmission member 130, the load transmission member 130 moves in −Z direction. At this time, the pressing force applied to the load transmission member 130 is transmitted to the brush device 80 through the load transmission member 130 and the brush support shaft 81. Therefore, during the cleaning process of the substrate W, the brush device 80 can be pressed against the substrate W by using the pressing force generated from the air cylinder device 110.

The load sensor 310 detects the pressing force through the second force transmission point P2 of the load transmission member 130 contacting the contact member 311 and the pressing force acting on the contact member 311 in −Z direction. Accordingly, based on the detection result of the pressing force by the load sensor 310, the magnitude of the pressing force applied from the air cylinder device 110 to the load transmission member 130 can be adjusted.

Here, the first force transmission point P1 of the load transmission member 130, the second force transmission point P2 of the load transmission member 130, and the linear guide 200 overlap with a virtual line L11 extending in X-direction when viewed in a plan view. Therefore, in a state where a downward pressing force is applied to the first force transmission point P1 of the load transmission member 130 and the first force transmission point P1 contacts the contact member 311, no moment around the virtual line L11 is generated in the linear guide 200.

In this case, the occurrence of a large variation in the connection state between the rail 210 and the slider 220 of the linear guide 200 due to generation of a moment in the linear guide 200 is suppressed. Therefore, the deviation between the pressing force applied from the air cylinder device 110 to the first force transmission point P1 of the load transmission member 130 and the pressing force acting from the second force transmission point P2 of the load transmission member 130 to the contact member 311 is suppressed. Accordingly, the detection accuracy of the pressing force by the load sensor 310 is improved. Therefore, based on the detection result of the load sensor 310, the magnitude of the pressing force applied from the air cylinder device 110 to the load transmission member 130 can be accurately adjusted. As a result, the accuracy of cleaning the substrate W by using the brush device 80 is improved.

(b) During the cleaning process of the substrate W, a reaction force acts on the third force transmission point P3 of the load transmission member 130 from the substrate W through the brush device 80 and the brush support shaft 81. Even in such a case, when viewed in a plan view, the third force transmission point P3 overlaps with the virtual line L11. Accordingly, a moment is not generated around the virtual line L11 in the linear guide 200. As a result, during the cleaning process of the substrate W, the force applied from the air cylinder device 110 to the load transmission member 130 can be transmitted to the brush device 80 more accurately.

(c) The linear guide 200 has a configuration in which the first attachment part 240 and the second attachment part 250 of the slider 220 are attached to the first side part 211 and the second side part 212 of the rail 210 via the balls BA, respectively. In this manner, in the linear guide 200 that moves the slider 220 relative to the rail 210 by rolling the balls BA, a pressure can be applied to the rolling bodies in advance. Accordingly, the accuracy of the movement of the slider 220 relative to the rail 210 can be easily improved.

Also, the linear guide 200 is fixed to the pillar member 140, so that the rail 210 extends in Z-direction. In this state, the first side part 211 and the second side part 212 of the rail 210 are arranged in Y-direction. In this case, when a Y-direction force acts between the rail 210 and the slider body, there is a high possibility that a differential slip occurs in some of the balls BA.

However, in the brush arm 41, a moment around the virtual line L11, that is, a moment around an axis along X-direction, is not generated in the linear guide 200. Therefore, a Y-direction force is unlikely to act between the rail 210 and the slider body. Accordingly, variation is unlikely to occur in the connection state between the rail 210 and the slider 220 in the linear guide 200.

### 11. Other Embodiments

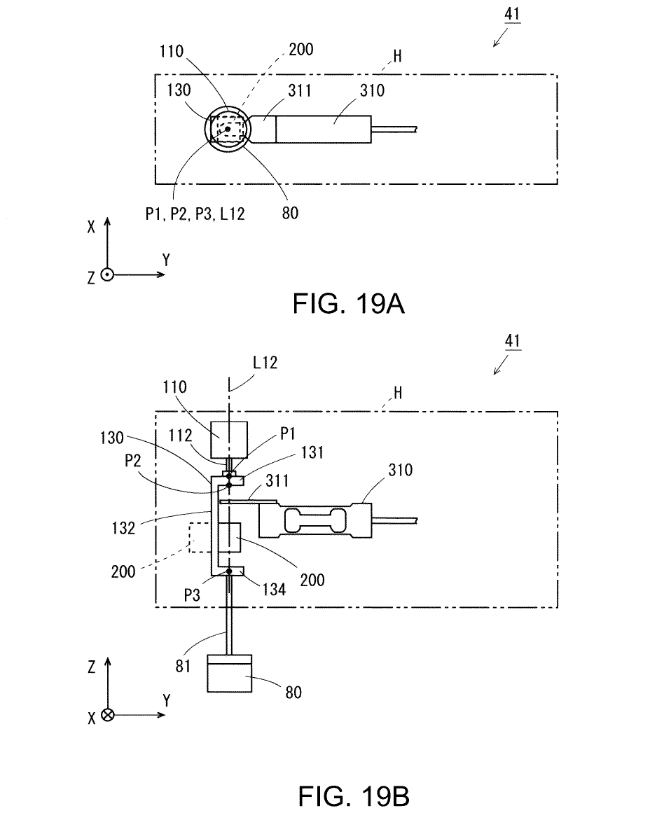

(a) In the substrate cleaning device 1 according to the above embodiment, the brush arm 41 may have the following configuration instead of the configuration described in FIG. 4 to FIG. 7. FIGS. 19A and 18B are diagrams showing an example of the brush arm 41 according to another embodiment. FIG. 19A is a schematic plan view of the brush arm 41. Also, FIG. 19B is a schematic side view of one side of the brush arm 41. In FIGS. 19A and 19B, only the components necessary for describing the features of this example, among the components, in the brush arm 41 are shown.

As shown in FIGS. 19A and 19B, in the brush arm 41 of this example, the air cylinder device 110 is provided at a position inside and at an upper part of the housing H via a bracket not shown. In this state, the cylinder rod 112 of the air cylinder device 110 extends downward from the lower end part of the air cylinder device 110.

The load transmission member 130 is provided directly below the air cylinder device 110. The load transmission member 130 of the example includes the load reception part 131, the lifting support part 132, and the load transfer part 134, as shown in FIG. 19B. The load reception part 131 has a plate shape and is arranged parallel to a horizontal plane (a plane parallel to X-direction and Y direction). Also, the load reception part 131 is connected to the tip part (lower end part) of the cylinder rod 112 of the air cylinder device 110. The lifting support part 132 extends downward from a portion of the load reception part 131 by a predetermined distance. The lifting support part 132 is connected to the housing H via the linear guide 200.

The load transfer part 134 is formed to bend in Y-direction from the lower end part of the lifting support part 132. The load transfer part 134 has a plate shape and faces the lower surface of the load reception part 131. The upper end part of the brush support shaft 81 is connected to the load transfer part 134. Inside the housing H, a self-weight offset mechanism (not shown) is provided to support the brush device 80, the brush support shaft 81, and the load transmission member 130.

The load sensor 310 is provided on the side of the load transmission member 130. The contact member 311 connected to the load sensor 310 is arranged between the load reception part 131 and the load transfer part 134 in Z-direction, so as to be separated by a predetermined distance from the lower surface of the load reception part 131.

In the load transmission member 130, the portion of the load reception part 131 to which the cylinder rod 112 is connected is referred to as the first force transmission point P1. Also, the portion of the load reception part 131 that faces the contact member 311 connected to the load sensor 310 in Z-direction is referred to as the second force transmission point P2. Also, the portion of the load transfer part 134 to which the brush support shaft 81 is connected is referred to as the third force transmission point P3.

With the air cylinder device 110 operating, the force generated in the cylinder rod 112 is applied as a pressing force to the first force transmission point P1 of the load transmission member 130. In this case, the pressing force applied to the first force transmission point P1 is transmitted from the third force transmission point P3 to the brush device 80 through the brush support shaft 81 in a state where the second force transmission point P2 of the load transmission member 130 is separated from the contact member 311. Meanwhile, the pressing force applied to the first force transmission point P1 acts from the second force transmission point P2 to the contact member 311 in a state where the second force transmission point P2 of the load transmission member 130 is in contact with the contact member 311. Accordingly, the pressing force applied to the load transmission member 130 is detected by the load sensor 310.

In such configuration, in this example, the first force transmission point P1, the second force transmission point P2, and the third force transmission point P3 where the pressing force is transmitted between multiple members are positioned on a virtual line L12 that passes through the axis of the brush support shaft 81. Also, the linear guide 200 is also positioned on the virtual line L12.

In this case, in the case where the pressing force is applied from the air cylinder device 110 to the load transmission member 130, a moment is not generated in the linear guide 200. Therefore, during the brush pressing force adjustment process, the pressing force applied to the load transmission member 130 by the air cylinder device 110 and the value of the pressing force detected by the load sensor 310 do not deviate from each other. Also, during the cleaning process of the substrate W, the pressing force applied to the load transmission member 130 by the air cylinder device 110 and the actual pressing force applied from the brush device 80 to the substrate W do not deviate from each other.

As shown by the dotted line in FIG. 19B, the linear guide 200 may be provided at a position deviated from the virtual line L12. Even in such a case, almost no moment is generated in the linear guide 200. Therefore, the pressing force can be detected with high accuracy. Also, a desired pressing force can be applied to the substrate W with high accuracy.

(b) In the brush arm 41 according to the above embodiment, the force generated in the cylinder rod 112 of the air cylinder device 110 is applied to the load transmission member 130 via the pressing mechanism 120, but the disclosure is not limited to this. As described in the example of FIGS. 19A and 19B, the force generated in the cylinder rod 112 of the air cylinder device 110 may be directly applied to the load transmission member 130. In this case, the pressing mechanism 120 becomes unnecessary, the brush arm 41 can be miniaturized, and the number of parts of the brush arm 41 can be reduced.

(c) In the brush arm 41 according to the above embodiment, a bearing (so-called rolling bearing) including multiple balls BA is used for the linear guide 200. Also, the linear guide 200 has a two-row structure in which the rail 210 has two guide grooves gr1 and gr2. However, the disclosure is not limited to this. For the linear guide 200, a rolling bearing having a four-row structure in which the rail 210 has four guide grooves may be used.

(d) In the brush arm 41 according to the above embodiment, a rolling bearing is used for the linear guide 200, but the disclosure is not limited to this. For the linear guide 200, other bearings such as a sliding bearing may be used instead of the rolling bearing.

(e) The load transmission member 130 according to the above embodiment is configured as a single member, but the disclosure is not limited to this. The load transmission member 130 may have a configuration in which multiple members are connected to each other. Also, in the brush arm 41 according to the above embodiment, the force generated in the air cylinder device 110 acts to press the first force transmission point P1 of the load transmission member 130 downward by the pressing mechanism 120, but the disclosure is not limited to this. The brush arm 41 may be configured so that the force generated in the air cylinder device 110 presses the first force transmission point P1 of the load transmission member 130 upward.

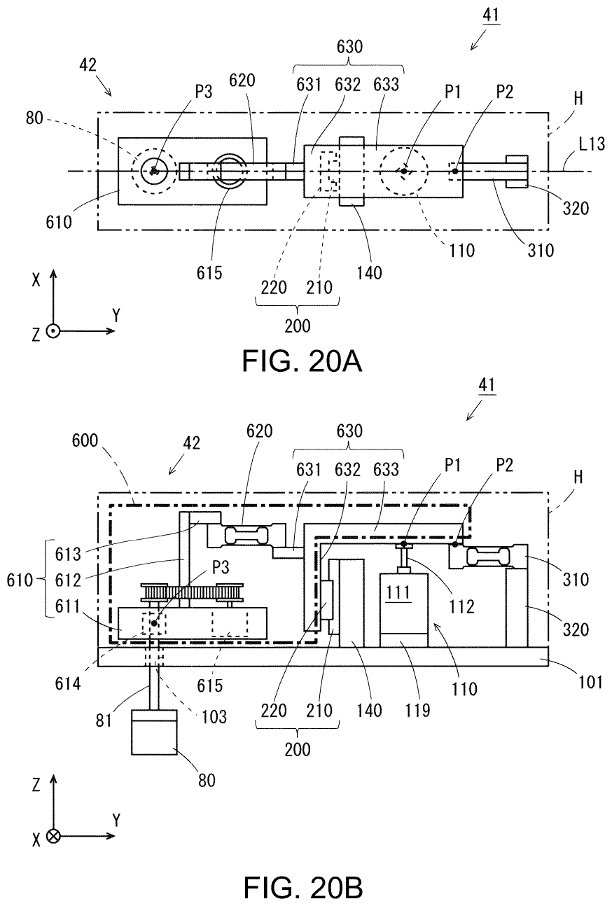

FIGS. 20A and 20B are diagrams showing an example of the brush arm 41 according to still another embodiment. FIG. 20A is a schematic plan view of the brush arm 41. Also, FIG. 20B is a schematic side view of one side of the brush arm 41. In FIGS. 20A and 20B, only the components necessary for describing the features of this example among the multiple components in the brush arm 41 are shown.

In the brush arm 41 of FIGS. 20A and 20B, similar to the example of the brush arm 41 according to the above embodiment, the air cylinder device 110 is provided via the cylinder base 119 at a position shifted in +Y direction from the central portion of the base member 101.

On the base member 101, the pillar member 140 is further provided at a position shifted in −Y direction from the air cylinder device 110. The pillar member 140 extends upward (+Z direction) from the upper surface of the base member 101 by a fixed length.

A buoyancy imparting member 630 is attached to the pillar member 140 via a linear guide 200. Specifically, the linear guide 200 includes a rail 210 and a slider 220. The rail 210 is attached to the pillar member 140, and the slider 220 is attached to the buoyancy imparting member 630. Accordingly, the buoyancy imparting member 630 is supported movably in the upper-lower direction relative to the pillar member 140. In this example, the rail 210 is fixed to the pillar member 140 so as to extend in Z-direction. In this state, the first side part 211 (FIG. 10) and the second side part 212 (FIG. 10) of the rail 210 are arranged in X-direction.

The buoyancy imparting member 630 is a single member that includes a sensor support part 631, a vertical part 632, and a horizontal part 633. The vertical part 632 is a portion to which the slider 220 of the linear guide 200 is attached, and extends in the upper-lower direction in a state where the buoyancy imparting member 630 is attached to the pillar member 140. The sensor support part 631 is formed to protrude a fixed length in −Y direction from a position near the upper end part of the vertical part 632. The horizontal part 633 is formed to extend a certain length in +Y direction from the upper end part of the vertical part 632. The tip part of the horizontal part 633 (the end part of the horizontal part 633 facing +Y direction) is positioned in +Y direction relative to the air cylinder device 110.

The load sensor 310 is provided below the tip part of the horizontal part 633. The load sensor 310 is fixed to the base member 101 via a sensor base 320. The load sensor 310 of this example is a Roberval-type load cell. The load sensor 310 detects the load received from the horizontal part 633 (the load obtained by canceling the force generated by the air cylinder device 110 from the self-weight of a load transmission member 600 to be described later) through the tip part of the horizontal part 633 contacting the load detection portion of the load sensor 310.

A load sensor 620 is attached to the tip part of the sensor support part 631 (the end part of the sensor support part 631 facing −Y direction). The load sensor 620 of this example is a Roberval-type load cell. Additionally, a brush support member 610 is attached to the load detection portion of the load sensor 620. Accordingly, the load sensor 620 detects the load received from the brush support member 610.

As described above, the brush support member 610 is linked to the buoyancy imparting member 630 via the load sensor 620. In this state, the brush support member 610 is positioned at the brush support part 42 of the brush arm 41.

The brush support member 610 is a single member that includes a body part 611, a support part 612, and a linking part 613. The linking part 613 is attached to the load detection portion of the load sensor 620 and extends a fixed length in −Y direction from the load sensor 620. The support part 612 extends downward from the tip part of the linking part 613. The body part 611 is connected to the lower end of the support part 612. In this state, the body part 611 is separated from the upper surface of the base member 101.

The body part 611 of this example has a block shape having a fixed length in each of X-direction, Y direction, and Z direction. A bearing 614 and a motor 615 are held inside the body part 611. A portion of the brush support shaft 81 that supports the brush device 80 is inserted into the bearing 614 from below the housing H through a through hole 103 formed in the base member 101. Accordingly, the brush device 80 is rotatably supported by the brush support member 610 through the brush support shaft 81 and the bearing 614.

A portion of the brush support shaft 81 (the upper end part of the brush device 80 in the example of FIGS. 20A and 20B) and the rotation shaft of the motor 615 held in the body part 611 of the brush support member 610 are connected by two pulleys and a belt. The motor 615 operates under the control of a control part not shown. During the operation of the motor 615, the rotational force generated by the motor 615 is transmitted from the rotation shaft of the motor 615 to the brush support shaft 81 through the two pulleys and the belt, and the brush device 80 rotates.

Here, in the brush arm 41 of FIGS. 20A and 20B, as shown by the thick dash-dot line frame in the lower part of FIGS. 20A and 20B, the brush support member 610, the load sensor 620, and the buoyancy imparting member 630 can be handled integrally. Therefore, in the brush arm 41 of FIGS. 20A and 20B, the configuration including the brush support member 610, the load sensor 620, and the buoyancy imparting member 630 can be regarded as the load transmission member 600 corresponding to the load transmission member 130 according to the above embodiment.

According to the above configuration, the load transmitted from the load transmission member 600 to the brush device 80 is adjusted by the air cylinder device 110 pressing the load transmission member 600 upward. For example, in the case where the air cylinder device 110 presses the load transmission member 600 with a force corresponding to the self-weight of the load transmission member 600, the pressing force of the brush device 80 against the substrate W can be made substantially 0. On the other hand, in the case where the air cylinder device 110 does not press the load transmission member 600, the pressing force of the brush device 80 against the substrate W becomes substantially equal to the self-weight of the load transmission member 600. To adjust the pressing force of the brush device 80 in this manner, the load detection results by the load sensors 310, 620 are used.

In the brush arm 41 of FIGS. 20A and 20B, the portion of the buoyancy imparting member 630 which the cylinder rod 112 of the air cylinder device 110 contacts corresponds to the first force transmission point P1 according to the above embodiment. Also, the portion of the buoyancy imparting member 630 which the load sensor 310 contacts corresponds to the second force transmission point P2 according to the above embodiment. Furthermore, the portion of the brush support member 610 where the brush support shaft 81 is connected via the bearing 614 corresponds to the third force transmission point P3 according to the above embodiment.

Therefore, also in the example of FIGS. 20A and 20B, in the case where a force in Z-direction acts on any of the first force transmission point P1, the second force transmission point P2, and the third force transmission point P3, a rotational moment due to the force acting on any of the points may be generated in the linear guide 200.

Regarding this point, as shown in the upper part of FIGS. 20A and 20B, in the brush arm 41 of this example, the first force transmission point P1, the second force transmission point P2, and the linear guide 200 are arranged to overlap with a virtual line L13 extending in Y-direction in a plan view.

According to this positional relationship, in both the case where the first force transmission point P1 of the load transmission member 130 contacts the cylinder rod 112 of the air cylinder device 110, and the case where the second force transmission point P2 of the load transmission member 130 contacts the contact member 311 of the load sensor 310, no rotational moment around an axis parallel to the virtual line L13 is generated in the linear guide 200. Therefore, based on the detection result of the load sensor 310, the magnitude of the pressing force applied from the air cylinder device 110 to the load transmission member 600 can be adjusted with high accuracy.

Also, in this example, the third force transmission point P3 overlaps with the virtual line L13 extending in Y-direction when viewed in a plan view. According to this positional relationship, during the cleaning process of the substrate W, no rotational moment around an axis parallel to the virtual line L13 is generated in the linear guide 200. As a result, during the cleaning process of the substrate W, the force applied from the air cylinder device 110 to the load transmission member 130 can be transmitted to the brush device 80 more accurately.

(f) In the brush arm 41 according to the embodiment, the brush support shaft 81 is connected to the load transmission member 130 via the upper bearing part 420, but the disclosure is not limited to this. The brush support shaft 81 and the load transmission member 130 may be provided to be separable from each other. That is, the load transmission member 130 may contact the upper end part of the brush support shaft 81 only in the case of receiving a load from the air cylinder device 110, and may transmit a pressing force to the brush support shaft 81.

(g) The brush device 80 according to the embodiment is supported by the brush support shaft 81 to be rotatable, but the disclosure is not limited to this. The brush device 80 may be supported by the brush support shaft 81 to be non-rotatable. In this case, it is not necessary to provide the motor 510 or the like in the brush arm 41. Therefore, miniaturization of the brush arm 41 and reduction in the number of parts of the brush arm 41 become possible.

(h) In the substrate cleaning device 1 according to the embodiment, the substrate holding device 10 has a so-called mechanical chuck type configuration in which multiple holding pins 12 hold the substrate W by contacting the outer peripheral end part of the substrate W, but the disclosure is not limited to this. The substrate holding device 10 may have a suction type configuration that sucks and holds the central portion of the lower surface of the substrate W.

### 12. Correspondence Relationship Between Each Component of Claims and Each Part of Embodiment

Hereinafter, examples of the correspondence between each component of the claims and each element of the embodiment will be described, but the disclosure is not limited to the following examples. As each component of the claims, various other elements having the configuration or function described in the claims can also be used.

In the embodiment, the brush device 80 is an example of a cleaning tool, the first force transmission point P1 of the load transmission member 130 is an example of a first portion of a force transmission body, the second force transmission point P2 of the load transmission member 130 is an example of a second portion of the force transmission body, the load transmission member 130 is an example of the force transmission body, −Z direction is an example of a first direction, and +Z direction is an example of a second direction.

Also, the linear guide 200 is an example of a linear guide, the air cylinder device 110 and the pressing mechanism 120 are examples of a force applying part, the contact member 311 is an example of a contact part, the load sensor 310 is an example of a force detection part, the virtual lines L11 and L13 are examples of virtual lines, and the substrate cleaning device 1 and the substrate processing device 800 are examples of substrate processing devices.

Also, the lower end part of the brush support shaft 81 is an example of a first end part of a support shaft, the upper end part of the brush support shaft 81 is an example of a second end part of the support shaft, the brush support shaft 81 is an example of the support shaft, the third force transmission point P3 of the load transmission member 130 is an example of a third portion of the force transmission body, the base member 101 is an example of a base member, the lower bearing part 410, the upper bearing part 420, the self-weight offset mechanism 490, and the pulley 521 are examples of a shaft support mechanism, and the coil spring of the self-weight offset mechanism 490 is an example of a self-weight offset member.

Also, the balls BA are examples of multiple rolling bodies, the first side part 211 of the rail 210 is an example of a first side part of a rail, the second side part 212 of the rail 210 is an example of a second side part of the rail, the rail 210 is an example of the rail, the first attachment part 240 of the slider body is an example of a first attachment part of a slider, and the second attachment part 250 of the slider body is an example of a second attachment part of the slider.

Also, the slider 220 is an example of a slider, the two guide grooves gr1 and gr2 of the rail 210 are examples of guide grooves formed in the first side part and second side part of the rail, and Y-direction described in FIG. 4 to FIG. 7 and X-direction described in FIG. 20 are examples of a third direction.

### 13. Summary of Embodiments

[1] A substrate processing device according to a first aspect includes: a cleaning tool, cleaning a substrate; a force transmission body, having a first portion and a second portion; a linear guide, supporting the force transmission body to be movable in a first direction and a second direction opposite to the first direction; a force applying part, applying a force in the first direction or a force in the second direction to the first portion of the force transmission body; and a force detection part, having a contact part able to contact the second portion and detecting a force acting in the first direction from the second portion to the contact part. The force transmission part is able to transmit the force applied from the force applying part to the first portion to the cleaning tool, and the first portion, the second portion, and the linear guide overlap with a virtual line that intersects the first direction and the second direction when viewed in the first direction.

In the substrate processing device, with the force applying part applying a force to the first portion of the force transmission body, the force transmission body moves in the first direction or the second direction by the linear guide. Alternatively, the force transmission body is maintained in a stop state in the first direction or the second direction. At this time, the force applied from the force applying part to the force transmission body is transmitted to the cleaning tool. Therefore, while the cleaning tool is pressed against the substrate, the substrate can be cleaned with a force corresponding to the force generated from the force applying part.

With the second portion of the force transmission body contacting the contact part, the force detection part detects the force acting in the first direction on the contact part. Therefore, when the second portion of the force transmission body contacts the contact part in a state where a force is applied from the force applying part to the force transmission body, the force detection part detects a force corresponding to the force applied from the force applying part to the force transmission body. Thereby, the magnitude of the force applied from the force applying part to the force transmission body can be adjusted based on the detection result of the force detection part.

Here, the first portion, the second portion, and the linear guide overlap with a virtual line that intersects the first direction and the second direction when viewed in the first direction. Therefore, in the state where a force is applied from the force applying part to the first portion of the force transmission body and the second portion of the force transmission body contacts the contact part, no moment around the virtual line is generated in the linear guide. Therefore, divergence between the force applied from the force applying part to the first portion and the force acting from the second portion to the contact part due to generation of a moment around the virtual line in the linear guide is suppressed. Accordingly, the force detection accuracy by the force detection part is improved. Based on the detection result of the force detection part, the magnitude of the force applied from the force applying part to the force transmission body can be accurately adjusted. As a result, the accuracy of substrate cleaning using the cleaning tool is improved.

[2] The substrate processing device according to [1] may further include a support shaft,

having a first end part and a second end part and extending in the first direction and the second direction, and supporting, at the first end part, the cleaning tool. The force transmission body may further have a third portion connected to the second end part of the support shaft. The third portion may overlap with the virtual line when viewed in the first direction.

According to the above configuration, the third portion of the force transmission body is connected to the cleaning tool via the support shaft. When a force is applied from the force applying part to the first portion of the force transmission body, the force applied to the first portion acts on the cleaning tool from the third portion through the support spindle. Therefore, the substrate can be cleaned while pressing the cleaning tool against the substrate with a force corresponding to the force generated from the force applying part.

During the cleaning of the substrate, a reaction force acts on the third portion from the substrate via the cleaning tool and the support spindle. Even in such case, the third portion overlaps with the virtual line when viewed in the first direction. Accordingly, no moment around the virtual line is generated in the linear guide. As a result, during the cleaning of the substrate, it becomes possible to accurately transmit the force applied from the force applying part to the force transmission body to the cleaning tool.

[3] The substrate processing device according to [2] may further include: a base member,

supporting the linear guide; and a shaft support mechanism, supporting the support shaft on the base member to be movable in the first direction and the second direction. The force applying part may apply a force in the first direction to the first portion of the force transmission body. The first direction may be a direction from upper to lower. The second direction may be a direction from lower to upper. The shaft support mechanism may include a self-weight offset member that applies an upward force to the support shaft.

In such case, in a state where the force applying part does not apply force to the first portion of the force transmission body, the force from the force applying part is not transmitted to the support shaft and the cleaning tool. Accordingly, the support shaft and the cleaning tool are supported at a specific height position on the base member by the self-weight offset member.

Meanwhile, in a state where the force applying part applies a force to the first portion of the force transmission body, the force from the force applying part is transmitted to the support shaft and the cleaning tool. Accordingly, the support shaft and the cleaning tool move in the upper-lower direction. At this time, the substrate is cleaned through the cleaning tool contacting the substrate. In the case where the cleaning tool does not contact the substrate, the second portion of the force transmission body contacts the contact part of the force detection part, and the force acting on the contact part is thus detected.

[4] In the substrate processing device according to any one of [1] to [3], at least two of the

first portion, the second portion, and the linear guide overlap when viewed in the first direction.

In this case, the moment generated in the linear guide can be reduced within one virtual plane that includes the virtual line and extends in the first direction and the second direction. In this case, the divergence between the force applied from the force applying part to the first part and the force acting from the second part on the contact part is further suppressed.

[5] In the substrate processing device according to any one of [1] to [4], the linear guide

may include: multiple rolling bodies; a rail, having a first side part and a second part that face in directions opposite to each other and extending linearly; and a slider, having a first attachment part and a second attachment part respectively corresponding to the first side part and the second side part. Each of the first side part and the second side part of the rail may have a guide groove formed to be able to move each of the rolling bodies in a direction in which the rail extends. The slider may be configured to be movable along the rail by attaching the first attachment part to the first side part of the rail via some of the rolling bodies and attaching the second attachment part to the second side part of the rail via some other of the rolling bodies. The force transmission body may be attached to the slider. The rail may be fixed in a state of extending in the first direction and the second direction and in a state in which the first side part and the second side part are arranged in a third direction intersecting with the first direction, the second direction, and the virtual line.

According to the above configuration, no moment acts between the first side part, the rolling bodies, and the slider within another virtual plane that intersects the virtual line. Also, no moment acts between the second side part, the rolling bodies, and the slider within the other virtual plane. This makes it difficult for variations to occur in the connection state between the rail and the slider in the linear guide.

Furthermore, according to the linear guide, the accuracy of movement of the slider relative to the rail can be easily improved by applying pressure to the rolling bodies in advance.

What is claimed is:

1. A substrate processing device, comprising:
a cleaning tool, cleaning a substrate;
a force transmission body, having a first portion and a second portion;
a linear guide, supporting the force transmission body to be movable in a first direction and a second direction opposite to the first direction;
a force applying part, applying a force in the first direction or a force in the second direction to the first portion of the force transmission body; and
a force detection part, having a contact part able to contact the second portion and detecting a force acting in the first direction from the second portion to the contact part,
wherein the force transmission part is able to transmit the force applied from the force applying part to the first portion to the cleaning tool, and
the first portion, the second portion, and the linear guide overlap with a virtual line that intersects the first direction and the second direction when viewed in the first direction.

2. The substrate processing device as claimed in claim 1, further comprising a support shaft, having a first end part and a second end part and extending in the first direction and the second direction, and supporting, at the first end part, the cleaning tool,
wherein the force transmission body further has a third portion connected to the second end part of the support shaft, and
the third portion overlaps with the virtual line when viewed in the first direction.

3. The substrate processing device as claimed in claim 2, further comprising:
a base member, supporting the linear guide; and
a shaft support mechanism, supporting the support shaft on the base member to be movable in the first direction and the second direction,
wherein the force applying part applies a force in the first direction to the first portion of the force transmission body,
the first direction is a direction from upper to lower,
the second direction is a direction from lower to upper, and
the shaft support mechanism comprises a self-weight offset member that applies an upward force to the support shaft.

4. The substrate processing device as claimed in claim 1, wherein at least two of the first portion, the second portion, and the linear guide overlap when viewed in the first direction.

5. The substrate processing device as claimed in claim 1, wherein the linear guide comprises:
a plurality of rolling bodies;
a rail, having a first side part and a second part that face in directions opposite to each other and extending linearly; and
a slider, having a first attachment part and a second attachment part respectively corresponding to the first side part and the second side part,
wherein each of the first side part and the second side part of the rail has a guide groove formed to be able to move each of the rolling bodies in a direction in which the rail extends,
the slider is configured to be movable along the rail by attaching the first attachment part to the first side part of the rail via some of the rolling bodies and attaching the second attachment part to the second side part of the rail via some other of the rolling bodies,
the force transmission body is attached to the slider, and
the rail is fixed in a state of extending in the first direction and the second direction and in a state in which the first side part and the second side part are arranged in a third direction intersecting with the first direction, the second direction, and the virtual line.
